(19) United States
(12) Patent Application Publication
(10) Pub. No.: US 2005/0215073 A1
(43) Pub. Date: Sep. 29, 2005

(54) Wafer supporting member

(75) Inventors: Tsunehiko Nakamura, Kokubu-shi (JP); Yasushi Migita, Kokubu-shi (JP); Tohru Matsuoka, Kokubu-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/090,950

(22) Filed: Mar. 24, 2005

(30) Foreign Application Priority Data
Mar. 24, 2004 (JP) P 2004-87694

(51) Int. Cl. H01L 21/31

(52) U.S. Cl. 438/778

(57) ABSTRACT

The present wafer supporting member includes a supporting part composed of a planar insulating sheet having a pair of main surfaces, one serving as a mounting surface for mounting a wafer and the other having an adsorption electrode; a resin layer part provided below the adsorption part and a conductive base part provided below the resin layer part wherein the adsorption part has a thickness in a range of 0.02 to 10.5 mm, preferably 0.02 to 2.0 mm. The wafer supporting member further comprises a heater part provided with an insulating resin layer having heaters embedded therein between the resin layer part and the conductive base part. On a surface of the insulating resin layer concave portions are formed and filled with a resin having a composition different from that of the insulating resin layer in order to embed the concave portions.

### BACKGROUND OF THE INVENTION

1. Field of the Invention

The present invention relates to a supporting member for holding a wafer or a liquid crystal glass (hereinafter collectively referred to as a ‘wafer supporting member’), which is used in a method of manufacturing a semiconductor or liquid crystal, including etching for microfabrication of a semiconductor water and/or a liquid crystal glass, forming a thin film, exposing a photoresist film, etc.

2. Description of the Related Art

Conventional manufacturing of a semiconductor includes etching for micro-fabrication of a wafer, forming a thin film, exposing a photoresist film, etc., which uses a wafer supporting member for electrostatically adsorbing the wafer in order to hold it.

The wafer supporting member, as shown in FIG. 7, includes a ceramic substrate 54, a pair of adsorption electrodes 53 provided on the upper surface of the ceramic substrate, feeding terminals 58 for energizing the adsorption electrodes 53, and an insulating sheet 52 for covering the adsorption electrodes 53, the upper surface of the insulating sheet 52 being served as a mounting surface 52a for mounting the wafer being on the upper surface of the insulating sheet 52.

Such a wafer supporting member 51 is an object supporting device using an electrostatic coulomb force, which attracts the wafer W with an adsorption force F generated by forming the insulating sheet 52 having a dielectric constant ε with a thickness r, mounting the wafer W on the mounting surface 52a, and then applying a voltage V to the adsorption electrode 53 to create one half of a voltage V/2 volts between the wafer W and the adsorption electrode 53.
F=(ε/2)×(V²/4r²)

The adsorption force F as the electrostatic force serving as a force for supporting an object increases, as the thickness r of the insulating sheet 52 decreases and a voltage V increases. The adsorption force F increases as the voltage V increases, but the insulation of the insulating sheet 52 is broken when the adsorption force F becomes too large. Further, if there are voids such as pinholes on the insulating sheet 52, the insulation is also broken. Therefore, the surface of the insulating sheet 52 supporting the object is required to be smooth and without pinholes.

The adsorption force generally acts when the volume resistivity of the insulating sheet 52 is 10¹⁵ Ω·cm or more and, when the volume resistivity is in a range of 10⁸ to 10¹³ Ω·cm, so called a Johnson-Rahbek force acts as a stronger absorption force.

However, a conventional wafer supporting member as described in Japanese Unexamined Patent Application Publication No. 59-92782 is formed using a metal such as aluminum as an electrode and an organic film having glass or bakelite, acryl or epoxy materials as the insulating sheet for covering the electrode. Such insulating sheet has problems in heat-resistance, abrasion-resistance, chemical-resistance and so forth, as well as in cleanness since it has small hardness to cause generation of ground powders in use easy to stick on the semiconductor wafer, thereby adversely affecting the wafer.

In addition, as shown in FIG. 5, of Japanese Unexamined Patent Application Publication No. 58-123381 discloses a wafer supporting member 21 having a ceramic film formed by means of a spray forming as the insulating sheet 22. But this has disadvantages in that it composed of alumina having a low thermal conductivity and the insulating sheet 22 is porous, thereby exhibiting a bad cooling efficiency.

The wafer supporting member made of a ceramic element described in the above Patent Document No. 59-92782 requires the conductive base part attached to the bottom portion of the member in order to remove heat from the wafer W. As a solution, Patent Document 4 disclosed a wafer supporting member having an insulating adhesive layer composed of a planar ceramic body having an adsorption electrode embedded therein and a conductive base part, both of which are bonded to each other with a high-insulating silicone resin having the volume resistivity of 10¹⁵ Ω·cm or more. However, the wafer supporting member according to Japanese Unexamined Patent Application Publication No. 4-287344 has defects in that the conductive base part has part of the adsorption force remained, since a residual charge on the mounting surface remains on the insulating adsorption layer and has troubles to flow into the conductive base part, whereby the wafer W cannot be separated in a short time.

In Japanese Unexamined Patent Application Publication No. B-288376, as shown in FIG. 6, there is disclosed a wafer supporting member prepared by forming an anode oxide film 26 made of aluminum on the surface of an aluminum alloy substrate 24, then forming an amorphous aluminum oxide layer 22 with excellent plasma-resistance over the film 26 by 0.1 to 10 μm in thickness. However, a protective film with about 10 μm thickness is difficult to fill pinholes generated during a film forming step, resulting in penetration into the base part. The amorphous aluminum oxide layer with the thickness ranging of 0.1 to 10 μm eroded at once under a hard plasma condition and lacked practical availability. When formed in at least 10 m thickness, the oxide film exhibited a-disadvantage of striping out due to an internal stress during a film forming step. Considering that the amorphous aluminum oxide film and the anode oxide film made of aluminum have different volume resistivities, there are problems, for example, it requires time until the adsorption force becomes constant since the adsorption force does not function at once even when voltage is applied, adsorption/release specific response becomes bad such as generation of residual adsorption force since the adsorption force does not become zero (0) at once even when applied voltage is stopped, and also it sometimes incurs inconvenience in control of process since excessive time is required for detaching the wafer.

### SUMMARY OF THE INVENTION

Therefore, a first aspect of the present invention is to solve the problems regarding the residual adsorption mentioned above in a supporting member for adsorbing the wafer or the like using an electrostatic chuck.

In the water supporting member 101 having a heater part disclosed in Japanese Unexamined Patent Application Publication No. 2001-126851 and No. 2001-43961, as shown in FIG. 13, a heat-sealed polyimide film 405 is applied on a substrate 410 made of a metal such as aluminum while a heater 407 composed of a metallic foil having a predetermined heater pattern being attached over the applied substrate and, in addition to, the heat-sealed polyimide film 405 is heated and compressed over the prepared substrate by means of hot press to form an integrated member. Such heat-resistant polymer layer has adhesive ability as such and uses it to secure the metal foil sealed in a vacuum within the polyimide layer on the surface of the substrate 410 and to complete the wafer supporting member 401.

Further, in such wafer supporting device, it discloses a wafer supporting member which includes one main surface of a planar body as the mounting surface for the wafer W, an electrostatic adsorption electrode and an electrode composed of a heater embedded in the mounting surface with different depths, and a conductive base part having a cooling function to pass a cooling medium and cool the wafer, the conductive base part being bonded on the side opposite to the mounting surface of the planar body as the substrate (see Japanese Unexamined Patent Application Publication No. 2003-258065).

Additionally, when the wafer w is under etching process using the above wafer supporting member, the wafer W is adsorbed and fixed onto the mounting surface by first mounting the wafer W on the mounting surface, then applying voltage between the wafer W and the electrode for adsorption of electrostatic force to generate the electrostatic force. Following that, the wafer W is under the etching process which includes sending electric current to the heater electrode to heat the mounting surface, heating the wafer W adsorption-supported on the mounting surface and, at the same time, applying a high-frequency voltage between a plasma electrode (not shown) arranged on the upper surface of the wafer supporting number and the base part to generate the plasma, and finally introducing etching gas under this condition.

However, the wafer supporting member 401 with a heating function for the wafer W by the heater 407 while cooling the conductive base part 410 by flowing the cooling medium into the base part further requires emitting heat even when the wafer W is rapidly heated by the plasma or the like and, at the same time, heating the wafer W onto the mounting surface 405a while introducing heat from the heater 407 into the conductive base part 410. Accordingly, it was difficult to heat the wafer W at constant temperature in a range of room temperature to 100° C. with high accuracy and excellent uniformity.

Considering the reason of such problem, it is understood that the conventional wafer supporting member 401 has the polyimide film side with unevenness along the heater 407, thus, there will be difference in heat transfer to the wafer W by heat generated from the heater part 405 due to the unevenness if the uneven side becomes the mounting surface 405a and the conductive base part 410 is secured on the uneven side. As a result, it is expected that temperature unbalance within the wafer W is greater and adversely effects etching accuracy of the wafer W.

That is, when the wafer W is loaded on the uneven side of the polyimide film 405, heat of the heater 407 instantly transfers to the wafer W side at the convex portion of the polyimide film 405 on the heater 407 and increases temperature due to unevenness on the polyimide film 405, however, at a concave portion 408 between the heaters 407, the heat hardly transfers to the wafer W and the temperature is redirected compared to the wafer W side corresponding to the convex portion of the polyimide film 405. As a result, temperature difference within the wafer W sides corresponding to shape of the heater 407 was increased.

In case the conductive base part 410 is adhered and secured on the uneven side of the polyimide film 405, the heat generated at the convex portion of the heater 407 easily escapes to the conductive base part 410. In addition, the heat is hardly separated at the concave portion between the heaters 407. Therefore, it was surprisingly found that the temperature unbalance caused dependent on shape of the heater 407 on surface of the water W over the mounting surface 405a.

When the planar polyimide film 405 attaches to the conductive base part 410, micro space which occurs at interface between the film 405 and the base part 410 prevents heat transfer in this space, thereby resulting in increase of temperature difference in the wafer W side.

Accordingly, a second aspect of the present invention is to provide a wafer supporting member possible to uniformly heat inside the water side by a heater provided in the wafer supporting member.

In order to achieve the above-mentioned first aspect, there is provided the wafer supporting member according to the present invention, which includes 1) an adsorption part composed of an insulating sheet having a pair of main surfaces one of which serving as a mounting surface for mounting a wafer, while an adsorption electrode is provided on the other main surface of the insulating sheet, and 2) an insulating layer for covering the adsorption electrode; a resin layer part provided below the adsorption part; and 3) a conductive base part provided below the resin layer part and having a passage for allowing a cooling medium to flow, wherein the adsorption part has a thickness in a range of 0.02 to 10.5 mm, preferably 0.02 to 2.0 mm.

According to the first aspect of the invention, the wafer supporting member exhibits excellent separation properties of the wafer without the increase of a residual adsorption even when the wafer repeatedly adsorbs and separates and, at the same time, can prevent dielectric breakdown without variation of temperature on the mounting surface nor cracks of the insulating sheet even when plasma generates.

In order to achieve the above-mentioned second aspect, there is provided a wafer supporting member of the present invention further includes a heater part provided with an insulating resin layer having heaters embedded therein, between the resin layer part and the conductive base part, wherein concave portions are formed on a surface of the insulating resin layer opposite to the conductive base part and filled with a resin having a composition different from that of the insulating resin layer, and the heater part and the conductive base part are bonded to each other with an adhesive layer interposed therebetween. Preferably, the resin filled in the heater part has a surface roughness in a range of 0.2 to 2.0 μm in terms of an arithmetical mean roughness (Ra).

According to the wafer supporting member of the present invention, the resin part having heaters embedded therein and the concave portion on its surface and filled with a resin having a composition different from that of the insulating resin layer in order to till up the concave portion, can emit heat out of the conductive base part through a cooling medium because the adsorption part, the resin layer part and the conductive base part in the wafer supporting member are combined one another or are bonded to one another with an adhesive interposed therebetween and prevent overheat of the wafer W by plasma, etc., while reducing temperature difference in the wafer W side in a low temperature range of room temperature to 100° C. When the resin filled in the heating part has preferably the surface roughness in a range of 0.2 to 2.0 μm in terms of the arithmetical mean roughness (Ra), it can further enhance uniformity in heating the water supporting member.

According to the preferred embodiment, by the supporting part including one main surface of the planar body to mount the wafer as the mounting surface, and the adsorption electrode inside the planar body in the supporting part and/or on the other main surface of the mounting surface, the wafer supporting member can pass electric current to the adsorption electrode and make an electrostatic force to result in adsorption-securing the wafer on the mounting surface.

Additionally, by having thermal conductivity in the direction parallel to the mounting surface of the planar body in the supporting part in a range of 50 to 419 W/(m·K), the wafer supporting member can remarkably reduce temperature unbalance of the mounting surface.

In the heating part, since the insulating resin having heaters embedded therein contains a polyimide resin, it has excellent heat-resistance and electrical isolation when electric current flows in and heats the heater to heat the mounting surface of the planar body in the wafer supporting member, so that the heater can be conveniently embedded into the resin by thermocompression.

Further, by making the thermal conductivity of the insulating resin having heaters embedded therein, identical to that of the resin filled in the concave portion on surface of the heater part, the heat generated from the heater is transferred evenly to the mounting surface of the planar body, thereby the wafer supporting member can noticeably reduce temperature unbalance of the mounting surface.

Herein, the resin filled in the concave portion of the surface of the heater may include epoxy or silicone adhesive.

In addition, by defining a minimum thickness of the resin filled in the concave portion provided on the surface of the heater in a range of 0.01 to 1 μm, the wafer supporting member can noticeably reduce temperature unbalance on the mounting surface while reducing time to transfer heat on the mounting surface of the planar body, and increase throughput at machining process.

In manufacturing the wafer supporting member, the adhesive layer is preferably formed laminating alternative resin layers thinner than the adhesive layer between the heater part and the conductive base part several times, for exampler by laminating an adhesive layer between the heater part and the conductive base part multiple times by means of a screen printing. Further, the wafer supporting member can be manufactured by forming an adhesive layer on an adhesion side between the supporting part and the heater part, and/or the heater part and the conductive base part; placing the adhesive layer in an adhesion container then reducing inner pressure of the container; compressing the adhesive layer to adhere both parts; thereafter, increasing the inner pressure of the adhesive container to reinforce the adhesion. Moreover, the method for manufacturing the wafer supporting member preferably includes first contacting outer peripheral side of the adhesive layer; forming a closed space defined by the adhesive layer and a face to be adhered; and increasing the inner pressure of the adhesion container.

### BRIEF DESCRIPTION OF THE DRAWINGS

For a better understanding of the invention as well as other objects and features thereof, reference is made to the following detailed description to be read in conjunction with the accompanying drawings, wherein:

FIG. 1 is a cross-sectional view illustrating one embodiment of a wafer supporting member according to the present invention;

FIG. 2 is a cross-sectional view illustrating another embodiment of the wafer supporting member according to the invention;

FIG. 3 is a cross-sectional view illustrating an adhesion container of the wafer supporting member according to the invention;

FIG. 4 is a cross-sectional view illustrating an adhesion process for the wafer supporting member according to the invention;

FIG. 5 is a cross-sectional view illustrating another embodiment of the wafer supporting member according to the invention;

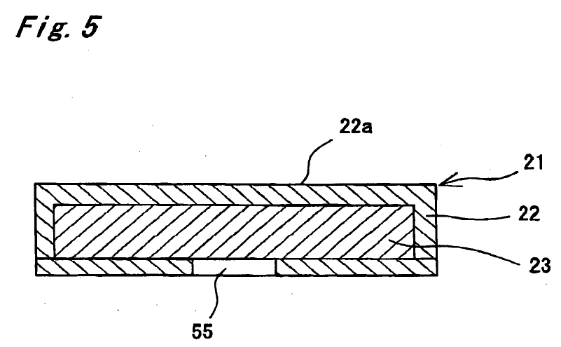

FIG. 6 is a cross-sectional view illustrating one embodiment of a conventional wafer supporting member;

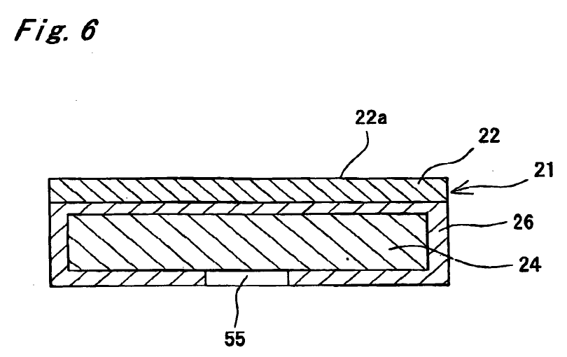

FIG. 7 is a cross-sectional view illustrating the wafer supporting member of the invention;

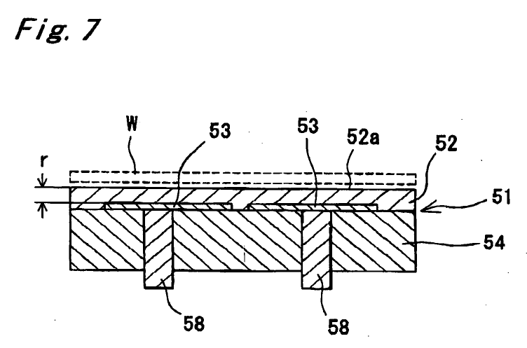

FIG. 8 is a cross-sectional view illustrating another embodiment of the invention;

FIG. 9 is a cross-sectional view illustrating another embodiment of the invention;

FIG. 10 is a cross-sectional view illustrating another embodiment of the invention;

FIG. 11 is a cross-sectional view illustrating the conventional wafer supporting member;

FIG. 12 is a cross-sectional view illustrating another conventional wafer supporting member;

FIG. 13 is a cross sectional view illustrating another conventional wafer supporting member;

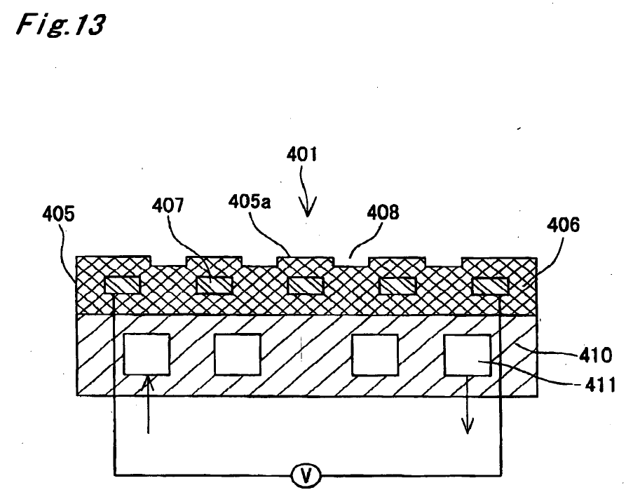

FIG. 14 is a cross-sectional view illustrating one embodiment of the wafer supporting member according to the invention;

FIG. 15 is a cross-sectional view illustrating another embodiment of the wafer supporting member according to the invention; and

FIG. 16 is a cross-sectional view illustrating another embodiment of the wafer supporting member according to the invention.

### DESCRIPTION OF THE PREFERRED EMBODIMENTS

### First Embodiment

Hereinafter, a first embodiment (an electrostatic chuck) of the present invention will be described in details below.

In the first embodiment of the present invention, the wafer supporting member includes an supporting part including a main surface as a mounting surface for mounting a wafer and the other main surface having an insulating layer provided with a built-in adsorption electrode and having an insulating sheet; the insulating resin layer optionally having a heater attached to the main surface having the adsorption election built therein; and a conductive base part with a passage through which cooling medium flows in, and the resin layer of the wafer supporting member has a volume resistivity in a range of 10⁸ to 10¹⁴ Ω·cm. Also, the resistance value between the mounting surface and the conductive base part is preferably in a range of 10⁷ to 10¹³ Ω. Both of the insulating sheet and the insulating layer are formed of the same planar ceramic body, in which the above adsorption electrode is preferably embedded therein.

Such insulating adsorption layer has preferably the thickness of not more than 10 mm, especially, in a range of 20 μm to 2 mm.

The resin layer is mainly composed of at least one of a silicone-based resin, a polyimide-based resin, a polyamide-based and an epoxy-based resin and preferably contains conductive particles. The conductive particles are preferably carbon or a metal. The resin layer preferably contains the conductive particles in a range of 0.01 to 30% by volume. The resin layer preferably has a thickness in a range of 0.001 to 2 mm.

The supporting part preferably includes an amorphous ceramic, especially, uniform amorphous ceramic consisting of oxides and has a thickness in a range of 10 to 100 μm. The supporting part preferably includes a rare gas element in a range of 1 to 10% by atom and has a Vickers harness of 500 to 1000 HV0.1. The supporting part is mainly composed of any one of aluminum oxide, a rare-earth oxide and a nitride.

The conductive base part is composed of any one metal component of aluminum and an aluminum alloy and any one ceramic component of silicon carbide and aluminum nitride, the content of the ceramic component being ranged from 50 to 90% by mass.

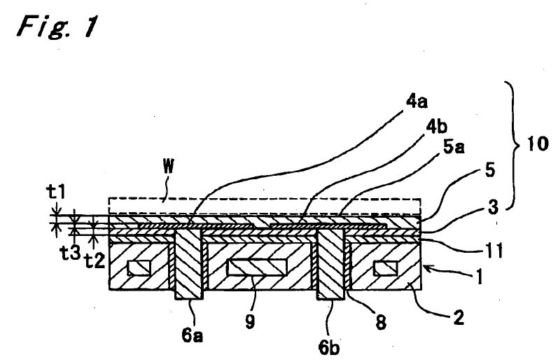

FIG. 1 shows a schematic structure of one example of the wafer supporting member 1 according to the present invention. The wafer supporting member 1 includes the main surface of the insulating sheet 5 as the mounting surface 5a for mounting the wafer W and the other main surface of the insulating sheet 5 having adsorption electrodes 4a and 4b, the insulating adsorption layer 10 with the insulating layer 3 below the adsorption electrodes 4a and 4b, and the conductive base part 2 bonded to the resin layer 11 together with the bottom side of the adsorption part 10.

The insulating layer 3 preferably includes oxide ceramics such as alumina, and ceramics a nitride and a carbide. The insulating sheet 5 may comprise the same composition as that of the insulating layer 3, or preferably include amorphous ceramics.

If the conductive base part 2 includes only metal component, the metal component is preferably selected regarding thermal expansion of either the insulating layer 3 or the insulating sheet 5. Metal usually has the thermal expansion greater than that of ceramics and thus, it is preferred that the conductive base part 2 is mainly composed of low-thermal expansion metals such as W, Mo, and Ti.

If the conductive base part 2 includes a combination of metal and ceramics, it preferably includes combined materials consisting of a framework made of porous ceramic body having three-dimensional net structure and aluminum or aluminum alloy tightly filled in pares of the ceramic body. Such construction can make thermal expansion coefficients of the insulating layer 3 and the insulating sheet 5 close to that of the conductive base part 2.

In a such case, it is possible to obtain a material having the thermal conductivity of about 160 W/(m·K) at the conductive base part 2 and, through the conductive base part 2, the heat transferred to the wafer W from atmosphere such as plasma can be easily removed.

The conductive base part 2 further has a flow passage 9 to pass the cooling medium. Since the heat of the wafer W is removed out of the wafer supporting member 1 using the cooling medium, temperature of the wafer W can be easily controlled to temperature of the cooling medium.

The wafer W is adsorbed to the mounting surface 5a by placing the wafer W on the mounting surface 5a, applying several hundreds V of adsorption voltages between the adsorption electrodes 4a, 4b from the feeding terminals 6a, 6b to express electrostatic adsorption force between the adsorption electrode 4 and the wafer W. Alternatively, the plasma generates with high efficiency at upper side of the wafer W by applying the RF voltage between the conductive base part 2 and opposite electrode (not shown).

The wafer supporting member 1 of the invention includes a resin layer 11 having the volume resistivity in a range of 10⁸ to 10¹⁴ Ω·cm. If the volume resistivity of the resin layer 11 is less than 10⁸ Ω·cm, the resin layer 11 contains excess amount of conductive materials to lead to decrease of adhesion intensity of the resin layer 11 for bonding the insulating adsorption layer 10 and the conductive base part 2, and stripping of the insulating adsorption layer 10 from the conductive base part 2 caused by thermal stress generated from minute difference in thermal expansion between the insulating adsorption layer 10 and the conductive base part 2. On the other hand, if it exceeds 10¹⁴ Ω·cm, the residual adsorption force increases to bring about non-releasing of the wafer W from the mounting surface 5a when the wafer W is repeatedly loaded on and separated out of the mounting surface 5a.

More preferably, the volume resistivity is in a range of 10⁹ to 10¹³ Ω·cm, the wafer W was easily separated from the mounting surface 5a.

The wafer supporting member 1 of the present invention has preferably the resistance value R between the mounting surface 5a and the conductive base part 2, in a range of 10⁷ to 10¹³ Ω. If the resistance value R is less than 10⁷ Ω, it induces the volume resistivity of the insulating sheet 5 to be lowered to less than 10⁸ Ω·cm and not to express so-called a Johnson-Rahbek force. It the resistance value R exceeds 10¹³ Ω, the residual charge remained on the mounting surface 5a is difficult to flow in the conductive base part 2, and/or the residual charge remained on lower side of the insulating layer stops flowing and does not escape out of the conductive base part 2. In addition, the adsorption and separation of the wafer W are repeatedly performed, the residual adsorption force increases to cause the wafer W not to separate out of the mounting surface 5a.

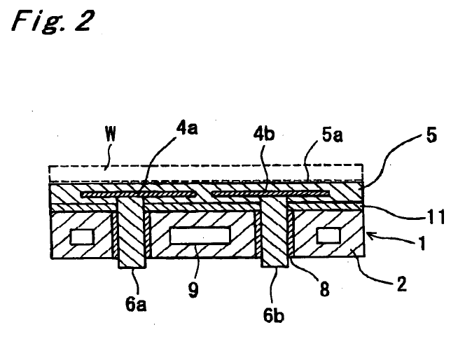

As shown in FIG. 2, the insulating sheet 5 and the insulating layer 3 are formed of the same planar ceramic body which may embed the adsorption electrode 4 inside. With this construction, both of them can adsorb the wafer W with the adsorption force sufficient to prevent separation of the insulating sheet 5 from the mounting surface 5a even when it adsorbs a large-sized liquid crystal substrate as the wafer W.

Thickness of the insulating adsorption layer 10 is preferably less than 10 mm. By having less than 10 mm of the thickness for the insulating adsorption layer 10 defined as an overall thickness over the insulating sheet 5, the adsorption electrode 4 and the insulating layer 3, it is possible to easily escape the residual charge of the mounting surface 5a to the conductive base part 2, so that the residual adsorption force may be not enlarged even when the water W is repeatedly adsorbed/separate out of the mounting surface 5a, and it allows the wafer W to separate easily in the short time.

Preferably, the insulating adsorption layer 10 has a thickness in a range of 20 μm to 2 mm. If the insulating adsorption layer 10 has a thickness of not more than 20 μm, the insulating sheet 5 may have the thickness of less than 15 μm and worried about to be under dielectric breakdown between the adsorption electrode 4 and the conductive base part 2. In case of exceeding 2 mm for the overall thickness of the insulating adsorption layer 10, heat of the wafer W may be not sufficiently transferred to the conductive base part 2. The overall thickness is preferably in a range of 30 μm to 500 μm, more preferably 50 μm to 200 μm.

A thickness t1 of the insulating sheet 5 is a distance from the upper surface of the adsorption electrode 4 to the upper surface of the mounting surface 5a It takes an average of the distances from five places in cross-sectional side perpendicular to the mounting surface 5a. Likewise, for each thickness t2 and t3 for the insulating layer 3 and the adsorption electrode 4, an average value is obtained by measuring thicknesses at five places the above cross-sectional side. Also, total of the thickness t1, t2 and t3 for the insulating sheet 5a, the insulating layer 3 and the adsorption electrode 4 becomes the overall thickness of the insulating adsorption layer.

The concave portions can be formed on the mounting surface 5a through a blast process and the like. Such concave portion may communicate a gas introduction hole passing through the mounting surface 5a from the back side of the conductive base part 2. Through the gas introduction hole, gas may be supplied igloo a space formed by the wafer W and the concave portion. The concave portion may also increase thermal conductivity between the wafer W and the mounting surface 5a.

It describes an estimation of t1 and t2 in this case.

The electrostatic chuck 1 of the invention is characterized in that the total thickness of the insulating sheet 5 and the insulating layer 3 is 20 to 2000 μm. This thickness enables heat transmitted from the wafer W to the mounting surface 5a to be radiated to the conductive base part 2. Therefore, it is possible to prevent an increase in temperature of the wafer or an increase in a temperature difference on the surface of the wafer W. When the total thickness is smaller than 20 μm, there is a fear that a dielectric breakdown will occur between the absorption electrode 4 and the conductive substrate 2. When the total thickness is larger than 2000 μm, heat generated from the wafer W cannot be sufficiently transmitted to the conductive substrate 2. Therefore, the total thickness is preferably 30 to 500 μm, and more preferably, 50 to 200 μm.

Further, a thickness t1 of the insulating sheet 5 is a distance from the upper surface of the adsorption electrode 4 to the upper surface of the mounting surface 5a, and is expressed by an average value of the distances of five places in a vertical traverse section of the mounting surface 5a. In addition, a thickness t2 of the insulating layer 3 is similarly expressed by an average value of the distances of five places in the vertical traverse section. The sum of the thickness t1 of the insulating sheet 5a and the thickness t2 of the insulating layer 3 is the total thickness.

Furthermore, concave portions can be formed in the mounting surface 5a by a blast processing method. A gas supply inlet is provided to communicate with the concave portion and to pass between the back side of the conductive substrate 2 and the mounting surface 5a, so that gas can be supplied to a space formed between the wafer W and the concave portions through the gas supply inlet. Thus, it is possible to improve heat conductivity between the wafer W and the mounting surface 5a.

The insulating sheet 5 preferably includes alumina, or nitride and/or carbide ceramics, and has at least 20 W/(m·K) of the thermal conductivity. The insulating sheet 5 consisting of a sintered ceramic preferably has the thickness in a range of 15 μm to 1500 μm to escape heat of the wafer W out of the conductive base part 2 with high efficiency. The thickness is more preferably in a range of 100 μm to 1000 μm and, most preferably 200 μm to 500 μm. Further, if the insulating sheet 5 has the thermal conductivity of at least 50 W/(m-K), the thickness thereof is preferably in a range of 200 μm to 1500 μm. Lowest limit of the thickness for the insulating sheet 5 is represented by the lowest value of thickness in view of cross-sectional side perpendicular to the mounting surface 5a and across transversely near diameter.

The insulating layer 3 comprising sintered ceramic has the thickness in a range of 15 μm to 1990 μm. If the thickness of the insulating layer 3 is less than 15 μm there is a danger of not maintaining insulation effect between the adsorption electrode 4 and the conductive base part 2. In case of exceeding 1990 μm, it has a problem that heat from the mounting surface 5a is not sufficiently transferred to the conductive base part 2. Such insulating layer 3 has more preferably at least 50 W/(m·K) of the thermal conductivity.

The insulating layer 3 has the thermal expansion near to that of the conductive base part 2 or the insulating sheet 5. The insulating layer 3 also includes a film with the same composition to the insulating sheet 5 having excellent insulation property, or borosilicate glass or borate glass. Otherwise, the insulating layer 3 may include amorphous ceramics. Herein, the amorphous ceramics means materials principally comprising a ceramic crystalline composition such as alumina, alumina-yttria oxides, nitrides and the like.

In case the insulating layer 3 is composed of the same amorphous ceramic composition as that of the insulating sheet 5, the insulating layer 3 has preferably a thickness in a range of 10 μm to 100 μm. If it is less than 10 μm, it may generate dielectric breakdown while, for more than 100 μm, mass-production thereof being deteriorated.

In addition, when the insulating layer 3 includes general glass composition other the amorphous ceramic, thickness of the insulating layer 3 is preferably 15 to 1990 μm to allow convenient heat transfer of the wafer W placed in the mounting surface 5a. In order to assure insulation between the conductive base part 2 and the adsorption electrode 4, the thickness is preferably not less than 10 μm, more preferably 20 μm to 1000 μm, and most preferably 50 μm to 300 μm.

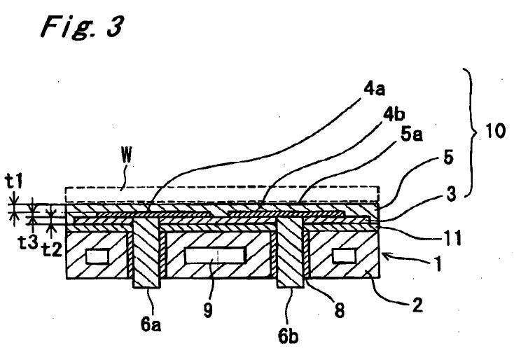

The insulating layer 3 consisting of glass composition has reduced corrosion-resistance under plasma atmosphere, thus, is preferably formed to be embedded by the insulating sheet 5 as shown in FIG. 3. With this construction, it can increase the corrosion-resistance of the water supporting member 1 simultaneously with ensuring high reliability of the electrostatic chuck 1, and extended durability of the wafer supporting member 1.

The wafer supporting member 1 of the present invention preferably has the resin layer 11 made of silicone, polyimide, polyamide, epoxy based materials with excellent adhesion to the insulating layer 3 consisting of alumina, nitrides, carbides, or amorphous film or glass layer thereof, and/or the conductive base part 2 consisting of metal or combination of metal and ceramics. Such resin layer 11 is preferably not stripped at the adhesion side even when thermal tress which generates due to a difference in thermal expansion of the insulating adsorption layer 10 and the conductive base part 2 is repeatedly applied.

If required lowering the volume resistivity of the resin layer 11, it is preferable to contain conductive particles in the resin layer 11. Including the conductive particles, the volume resistivity of the resin layer 11 can be freely controlled.

Such conductive particles preferably include carbon or metal component. Carbon particle includes, for example, carbon black or preferably Al as a metal component. Furthermore, it can contain Pt, Au and so forth. An average particle diameter of the carbon particle is preferably in a range of 0.05 μm to 3 μm while 0.5 μm to 5 μm for the metal particle, thereby easily mixing the conductive particles with a resin and having reduced unbalance of resistance for the resin layer 11.

The conductive particles which are in a range of 0.01 to 30% by volume relative to the resin component can preferably control the volume resistivity to 10⁸ to 10¹⁴ Ω·cm. Such % by volume of the conductive particles can be calculated multiplying an area ratio of the conductive particles occupied by its square in the cross section of the resin layer. Otherwise, it can be also obtained by a chemical quantitative analysis of the metal component occupied in a predetermined volume of the resin layer.

In order to escape residual charge out of between the insulating adsorption layer 10 and the conductive base part 2, the resin layer 11 has preferably a thickness in a range of 0.001 mm to 1 mm: If less then 0.001 mm, it occasionally causes that flatness of the lower surface of the insulating adsorption layer 10 and the upper surface of the conductive base part 2 increase more than 1 μm and/or it generates voids in the adhesive layer 11. When the thickness exceeds 1 mm, it is difficult to escape the residual charge out and, in case of repeated adsorption/separation of the wafer W, it is worried about increase of the residual adsorption.

The insulating sheet 5 of the invention is more preferably formed of only one layer of the insulating sheet composed of a uniform and amorphous ceramic. Such insulating sheet 5 has the same volume resistivity to that between the adsorption electrode 4 and the mounting surface 5a and, therefore, it exhibits rapid expression of the adsorption and continuous maintenance thereof if electrical field is evenly formed in the insulating sheet 5 and the adsorption voltage is applied thereto. If the application of adsorption voltage is stopped, the adsorption force becomes instantly zero (0) to lead to the escape of wafer W. Therefore, it provides the wafer supporting member 1 with high adsorption/separation properties.

The reason for using uniform and amorphous ceramic to produce the insulating sheet 5 is understood as follows:

The insulating sheet consisting of crystalline ceramics has hard and tight bonds of crystalline lattices. Such lattice has an lattice spacing hard to be altered by the stress. If the wafer supporting member has the insulating sheet composed of such crystalline ceramics, it lacks of function to relieve thermal stress such as an internal stress generated in the insulating sheet from the conductive base part 2 and/or the difference in thermal expansion therebetween. Contrary to the insulating sheet composed of such crystalline ceramics, the insulating sheet 5 composed of the amorphous ceramic can be formed at low temperature and exhibit variation of the lattice spacing depending on the stress at a relatively low temperature. As a result, the insulating sheet composed of the amorphous ceramic may have the internal stress less than that of the insulating sheet comprising the crystalline ceramic. In addition, the insulating sheet 5 composed of the amorphous ceramic is amorphous, and thus does not have periodic arrangement of atoms and have a structure easy to generate spaces in the atomic levels and to receive impurities. Accordingly, even when an internal stress generates caused by difference of the thermal expansion between the amorphous ceramic insulating sheet 5 and the conductive base part 2 and/or stress during a film forming step, it can carry out displacement at low temperature for the film forming step because of an irregular atomic arrangement and defects in atomic levels, so that the insulating sheet 5 can be displaced at a low film-forming temperature and it can reduce the stress applied to the insulating sheet 5. In addition, as the amorphous ceramic insulating sheet 5 has the composition beyond stoichiometric composition for crystals corresponding thereto, it exhibits that the defects in the atomic levels cagily occur and the stress between the insulating sheet 5 and the conductive base part 2 is easily relieved.

The insulating sheet 5 composed of the amorphous ceramic has preferably a thickness in a range of 15 μm to 200 μm. If less than 15 μm, the amorphous ceramic insulating sheet 5 is affected by voids or particles on surface of the conductive base part 2, and thus generating pin holes and/or extremely thin portion in the insulating sheet 5. Using the insulating sheet 5 in plasma, it becomes defects in the used area then occurs penetration of the adsorption electrode 4 through such defects in the insulating sheet 5 and generation of abnormal discharge or particles caused of dielectric breakdown of the insulating sheet 5. Accordingly, the insulating sheet b needs at least 15 μm in thickness.

If the insulating sheet 5 has a thickness of more than 200 μm, it requires about tens hours for information of the amorphous ceramic insulating sheet 5 thus lacks mass-production. Also, since it has an internal stress too high, the insulating sheet 5 may be occasionally stripped out of the adsorption electrode 4 or the insulating layer 3, and/or the conductive base part 2. Therefore, the insulating sheet 5 has preferably the thickness in a range of 30 μm to 70 μm, more preferably 40 μm to 60 μm.

In the invention, if the thickness of the insulating sheet 5 is at least 15 μm, it means that minimum thickness thereof on the conductive base part 2 is 15 μm or more. Likewise, the thickness of not more 200 μm means that average thickness of the insulating sheet 5 on the conductive base part 2 is not more than 200 μm. The average thickness is a value averaged from five parts by measuring the thickness of film at each of these five parts after equally dividing the insulating sheet 5 into fives.

In the amorphous ceramic insulating sheet 5, there exists argon as a rare inert element gas not reactive to other elements. By filling the rare inert element into the film 5, it can easily deform the insulating sheet 5 and increase efficiency for relieving the internal stress thereof. Therefore, it is possible to prevent great stress causing separation and/or stripping of the insulating sheet 5 even when the amorphous ceramic insulating sheet 5 according to the present invention having at least 15 μm in thickness is formed over the conductive base part 2 through the insulating layer 3 in order to cover and/or embed the adsorption electrode 4 with the film 5.

The amount of argon contained in the insulating sheet 5 is controlled to increase the gaseous pressure of argon, thereby enlarging a minus bias pressure applied to the conductive base part 2 under sputtering. As a result, the insulating sheet 5 can contain a lot of the argon ions ionized in the plasma atmosphere.

The amount of the argon contained in the insulating sheet 5 is preferably in a range of 1 to 10% by atom. More preferably, it can be in a range of 3 to 8% by atom. If the amount of a rare gas element is less than 1% by atom, the amorphous ceramic insulating sheet 5 cannot have a sufficient displacement. Therefore, it shows less effect of relieving the stress to result in easy generation of cracks even at about 15 μm in thickness. On the contrary, it is difficult to increase amount of rare gas element up to more than 10% by atom in manufacturing the water supporting member.

Other rare gas elements may be also used in a sputtering in place of the argon gas, however, in view of sputtering efficiency and expense of gases, the argon gas is preferable because of high sputtering efficiency and low cost thereof.

Regarding Quantitative Analysis of argon component in the insulating sheet 5, a comparable sample was firstly prepared by forming an amorphous ceramic film 2 in 20 μm over a sintered aluminum oxide body. This sample was analyzed under Rutherford Backscattering method to detect total atom weight and measure atom weight of argon element. Dividing total atom weight by the atom weight of argon element, calculated was in terms of percent by atom.

Since the amorphous ceramic insulating sheet 5 contains rare gas elements as mentioned above, it has smaller hardness compared to sintered ceramic body with similar composition. By incorporating rare gas elements, it can reduce the hardness and lower the internal stress of the insulating sheet.

The amorphous ceramic insulating sheet 5 is formed using a film forming step such as sputtering and has substantially no voids inside, although there are concave portions on surface of the insulating sheet 5. So, by grinding the surface of the insulating sheet 5 to remove the concave portions, it is possible to minimize surface area exposed to the plasma atmosphere at any time. Also, since there is no particle system such as multi-crystalline body in the insulating sheet 5, it is under the same etching process and seldom generates removal of particles. As a result, compared to conventional insulating sheet comprising widely known multi-sintered ceramic body, the present insulating sheet exhibits excellent plasma-resistance at each layer. In multi-crystalline ceramic sintered body including crystalline particle system, the roughness on area becomes up to about Ra 0.02. Whereas, the amorphous ceramic insulating sheet 5 according to the present invention can has noticeably reduced roughness down to Ra 0.0003 and be preferable in view of plasma-resistance.

The amorphous ceramic insulating sheet 5 including such rare gas element has preferably a Vickers hardness in a range of 500 to 1,000 HV0.1. If the hardness exceeds 1,000 HV0.1, the internal stress increases possible to cause separation of the insulating sheet 5. When the hardness is less than 500 HV0.1, the internal stress is reduced and rarely causes separation of the film 5 from the conductive base part. However, the hardness is so small that it may generate great grooves on the film 5 without difficulties, thereby lowering the voltage endurance. Sometimes, hard impurities penetrated between the wafer supporting member 1 including the wafer W and the mounting surface 5a generate dents on the insulating sheet 5. Such dents may lower the voltage endurance. Accordingly, the Vickers hardness of the insulating sheet 5 is preferably in a range of 500 to 1,000 HV0.1, more preferably 600 to 900 HV0.1.

The amorphous ceramic insulating sheet 5 preferably includes aluminum oxide, yttrium oxide, yttrium aluminum oxide or a rare-earth oxide, each having excellent plasma-resistance. Especially, yttrium oxide is preferred.

Furthermore, the conductive base part 2 according to the invention composed of a metal and a ceramic, has the thermal expansion coefficient essentially depending on the thermal expansion coefficient of a porous ceramic body forming a skeleton. Such ceramic preferably includes silicon carbide or aluminum nitride. The conductive base part 2 has also the thermal conductivity essentially depending on the thermal conductivity of a metal component filled in the pores. Thus, by changing the compounding ratio thereof, the thermal expansion coefficient and the thermal conductivity of the conductive base part 2 can be properly controlled. In particular, aluminum or an aluminum alloy with less effect to the wafer W is preferably contained in the conductive base part.

Therefore, the conductive base part 2 is composed of any one metal component of aluminum and an aluminum alloy and any one ceramic component of silicon carbide and aluminum nitride, the content of the ceramic component being ranged from 50 to 90% by mass. In addition to a commercially available aluminum alloy, the alloy containing a large amount of silicone may be also selected.

If amount of the ceramic component in the conductive base part 2 decreases below 50% by mass, intensity of the conductive base part 2 are sharply lowered and, at the same time, the thermal expansion coefficient of the conductive base part 2 has a high dependency with the thermal expansion coefficient of the aluminum alloy rather than that of the porous ceramic body. In case the thermal expansion coefficient of the conduction base part 2 is higher, difference of the thermal expansion between the conductive base part 2 and the amorphous ceramic insulating sheet 5 is enlarged so much that the insulating sheet 5 may be stripped out of the base part 2.

In contrast to the above, if the amount of the ceramic component in the conductive base part 2 exceeds more than 90% by mass, an open porosity of the ceramic becomes reduced and insufficient to charge aluminum alloy therein. As a result, thermal conduction and/or electric conduction are/is extremely lowered to make the conductive base part to loss its function. As the ceramics used, preferable is high rigidity porous ceramics having low thermal expansion such as silicon nitride, silicon carbide, aluminum nitride, alumina or the like. In order to fill tightly the aluminum alloy into puree, the porous ceramic body used has preferably a pore diameter in a range of 10 μm to 100 μm.

Considering process to fill metal in pores of the porous ceramic body, the porous ceramic body is previously heated in a press machine, followed by introducing molten metal then pressure-pressing treatment.

With SiC having a mass ratio in a range of 50 to 90%, the thermal expansion of the conductive base part 2 can be altered to about 11×10⁻⁶ to 5×10⁻⁶/° C., so that it can meet to the thermal expansion or the film forming step stress of the insulating sheet 5.

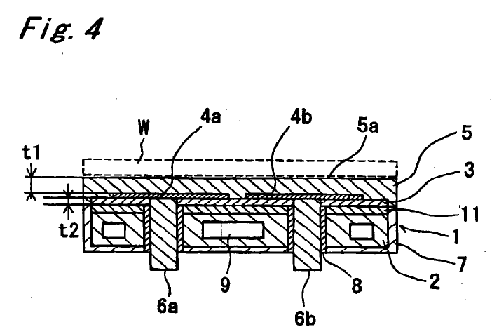

In an etching step using the wafer supporting member 1 according to the invention, a corrosive gas penetrates a little into a lateral side or atmosphere exposure face in the back side of the supporting member 1 protected by covering not described herein. Therefore, it is preferable to form a protective film 7 as shown in FIG. 4 to improve corrosion-resistance to plasma.

On the lateral side and the back side of the conductive base part 2 with less corrosion compared to the wafer mounting surface 5a, preferably formed is alumina thermal spraying film or anode oxide film of aluminum as the protective film 7. Such alumina thermal spraying film has preferably a thickness in a range of 50 μm to 500 μm. In case of the anode oxide film of aluminum, the thickness is preferably in a range of 20 μm to 200 μm.

Material for constructing surface of the conductive base part 2 is not critical when it selects formation of the alumina thermal spraying film as the protective film 7. However, if the protective film 7 is formed of the anode oxide film of aluminum, it needs to use aluminum alloy in formation of the surface of the conductive base part 2. For the conductive base part 2 which includes the porous ceramic body and the aluminum alloy impregnated in the ceramic body, the anode oxide film grows only at aluminum portion of the surface thereof even by forming the anode oxide film on the conductive part 2 while the ceramic portion being partially exposed. So, the conductive base part 2 represents lowered plasma-resistance and bad insulation between the plasma atmosphere and the conductive base part 2. Accordingly, when the aluminum alloy is impregnated, the conductive base part 2 having the surface with the aluminum alloy is preferably manufactured. Improved plasma-resistance is obtained by forming the anode oxide film of aluminum. And, surface insulation is provided by oxidation of aluminum on the surface of the conductive base part 2.

Hereinabove, the protective film 7 was described to cover the conductive base part 2. However, it will be of course understood that the protective film 7 may cover exposed portion of the insulating layer 3 as well as the surface of the conductive base part 2.

Hereinafter, the method for manufacturing the wafer supporting member 1 according to the present invention will be described in more detail.

First, the method includes laminating a plurality of ceramic green sheets made of alumina or aluminum nitride to prepare a laminate; and printing adsorption electrode 4 composed of a molybdenum paste or a tungsten paste on one main surface. On the other hand, another laminate is manufactured by laminating a plurality of alternative ceramic green sheets. Following then, a sintering process is carried out for both of them to form an integrated product after pressure-compressing process. The sintered body is under grinding process to grind outer circumference, following by grinding the sintered body below 2 mm in thickness to obtain a planar ceramic body embedding the adsorption electrode 4 therein.

After punching a hole at a desired position of the planar ceramic body to pass an absorption electrode 4, soldering-bonded are feeding terminals 6a and 6b. And, using silicone adhesive or epoxy adhesive, the conductive base part 2 composed of aluminum and the planar ceramic body are bonded together to obtain a wafer supporting member 1 of the invention.

Next, it describes the wafer supporting member 1 that is manufactured by impregnating a porous silicon carbide body with the aluminum alloy to form a conductive base part 2, forming aluminum alloy surface layer of the conductive base part 2, providing a anode oxide film as a protective film 7 having plasma-resistance on the conductive base part 2, and forming an amorphous ceramic insulating sheet 5 made of aluminum oxide through a sputtering.

Granulated materials are manufactured by adding silicon oxide (SiO₂) powder and binder in solvent to silicon carbide power having average particle size of about 60 μm then admixing together, and using a spray-dryer to form granules. After forming such granules into a disc-shaped body through rubber-press formation, the formed body is plasticized at about 1000° C. lower than conventional plasticization temperature under vacuum atmosphere to produce a porous ceramic body consisting of silicon carbide with 20% porosity. After then, such porous ceramic body is processed into the desired shape of a product.

The inventive method includes placing the porous ceramic body in die of a pressing machine, charging the molten aluminum alloy of at least 99% purity into the die after heating the die up to 680° C., and pressing it by falling a punch at 98 MPa. Subsequently, by cooling the pressed material, formed is a porous ceramic body filled with aluminum alloy as a metal component into pores. When the die has a size larger than the size of the porous ceramic body, aluminum alloy layer is formed on the entire surface of the conductive base part 2. By forming the aluminum alloy layer into the desired shape, manufactured is the conductive base part 2.

Surface of the aluminum alloy layer on the surface of the conductive base part 2 is under positive oxide coating treatment to produce the anode oxide film made of aluminum. The positive oxide coating treatment includes electrolysis using the conductive base part 2 as an anode and carbon as a cathode dipped in an acid such as oxalic acid or sulfuric acid, thereby generating γ-Al₂O₃ coating on surface of the aluminum alloy. Since the above coating is porous form, in case of dipping it in boiling water or reacting it with heated vapor, obtained is a protective film 7 comprising a dense boehmite (AlOOH) coating.

In order to form the insulating sheet 5 over the conductive base part 2 with the protective film 7, surface of the conductive base part 2 is under polishing process to obtain completed film side and finish the manufacturing after removing the protective film 7 on side placed with the insulating sheet 5 through cutting process.

In case alumina thermal spraying film is formed as the protective film 7 over the conductive base part 2, it is preferable to conduct thermal coating of the alumina after roughing surface of the conductive base part 2 through blasting and the like so that it can increase adhesion ability. Before the thermal coating of the alumina, it preferable to conduct thermal coating of Ni based metal film as a basic treatment so that it can more improve adhesion performance with the protective film 2. Such alumina thermal spraying film can be formed fusing and radiating alumina powder with a particle size of 40 μm to 50 μm under atmospheric plasma or vacuum plasma. In order to reinforce air tightness, it is preferably carried out under the vacuum plasma.

Since opened pores cannot be completely eliminated by only the thermal spraying film, the protective film 7 is further subjected to a sealing process comprising impregnating the film with organic or inorganic silicon compounds then heating to seal pores.

The amorphous ceramic insulating sheet 5 formed on finished face of the conductive base part 2 is manufactured through sputtering. At first, target subjected to formation of the insulating sheet 5 is setting in a sputtering machine in parallel plane form. In the machine, the target is aluminum oxide sintered body and the conductive base part 2 is setting in a holder made of copper on the opposite side of the target. The back side of the conductive base part 2 and the surface of the holder are painted with a liquid alloy composed of In and Ga then attached together to increase heat transfer between them and enhance cooling efficiency of the conductive base part 2. As a result, it is obtainable the insulating sheet 5 composed of a high quality amorphous ceramic.

As described above, the conductive base part 2 is setting in a sputtering chamber. Then, after controlling the degree of vacuum to 0.001 Pa, 25 to 75 sccm of an argon gas flows.

After then, applying a RF voltage between the target and the holder generates plasma. A presputtering portion of the target and the ceramic body 2 are under etching for several minutes, following by cleaning the target and the conductive base part.

The amorphous ceramic insulating sheet 5 made of aluminum oxide is spattered at d RF voltage of 3 to 9 W/cm². On the conductive base part 2, about −100 to −200 V bias voltage is applied to pull ionized molecules and/or ionized argon ions out of the target however, when the conductive base part 2 is insulated, surface of the conductive base part 2 is electrically charged by ionized argon ions and difficult to receive further argon ions. The argon ions entered in the film 5 emit electric charge, return original argon status and remain inside the film. In order to carry a larger amount of argon in the film, it requires the amorphous ceramic insulating sheet 5 to easily receive argon by making the charge to escape through the electric power supply of the conductive base part 2 in a film-forming, InGa layer, and the holder in this order during a film forming step.

If cooling of the conductive base part 2 gets worse, the amorphous ceramic insulating sheet 5 is partially crystallized and has voltage endurance or plasma-resistance partially deteriorated. The cooling of the conductive base part 2 includes pouring cooling water in a cooling plate of a cooling machine and fully cooling inside the holder of the plane to maintain temperature of the conductive base part 2 to about tens degree.

By forming an insulating sheet 5 at 3 μm/hour of a film-forming rate for about 17 hours, manufactured is the amorphous ceramic insulating sheet 5 having a film thickness of about 50 μm.

Thereafter, finishing process such as polishing makes surface of the amorphous ceramic insulating sheet 5 into a mounting surface 5a thereby completing the water supporting member 1. The mounting surface 5a is subjected to blasting or etching process to form concave portions. Between the concave portions and the wafer W gas is charged to make the thermal conductivity between the wafer W and the mounting surface 5a higher. Also, surface roughness of the mounting surface 5a made of amorphous ceramic can be reduced so that the mounting surface 5a occasionally adsorbs to the surface of the wafer W by a face contact. By forming the concave portions at 50% or more based on area of the mounting surface 5a, it is possible to prevent escape performance of the wafer W cause of face adsorption from getting worse.

### EXAMPLE 1

To the alumina powders, 0.5% by mass of calcium oxide and magnesium oxide in terms of weight were added, which was then mixed using a ball-mill for 48 hours. The obtained alumina slurry passed through a sieve of 325 meshes to remove the impurities attached on the ball or the ball-mill wall, and then dried in a dryer at 120° C. for 24 hours. To the obtained alumina powders, an acrylic binder and a solvent were added and mixed to prepare an alumina slurry. Using this alumina slurry, a green tape was prepared by a doctor blade method.

Further, several sheets of the green tape were laminated to form a laminate and, on one main surface thereof, an adsorption electrode made of a tungsten carbide paste was printed. On the other hand, several sheets of the separate ceramic green sheets were laminated to form a laminate, which was compressed under pressure to obtain a compressed laminate.

In addition, the laminate was baked in a baking furnace comprising a W heater and a W insulating material at 1600° C. under nitrogen atmosphere for 2 hours to form a planar ceramic body made of alumina having an outer diameter of φ305 mm and a thickness of 2 mm. This ceramic body was ground to have an outer diameter of φ300 mm and a thickness of 0.8 mm, and a hole passing through the adsorption electrode was processed to solder feeding terminals thereto.

The planar ceramic body was adhered to a conductive base part comprising an aluminum alloy and having a diameter of 300 mm and a thickness of 30 mm using an adhesive having a mixture of aluminum and a silicone resin to obtain electrostatic chuck samples Nos. 1 and 2.

Next, 15% by mass of CeO₂ as a sintering aid was added to the AlN powders having a purity of 99% and an average particle size of 1.2 μm. An organic binder and a solvent were added thereto to form a slip, and several sheets of aluminum nitride green sheets having a thickness of 0.5 mm were prepared using a doctor blade method. To one of aluminum nitride green sheets, a conductive paste was screen-printed in the form of an adsorption electrode.

For the conductive paste which would be the above electrostatic adsorption electrode, a conductive paste was used, which is adjusted its viscosity by mixing the WC powders and the AlN powders together.

The aluminum nitride green sheets were laminated in a predetermined order and thermally compressed under a pressure of 4.9 kPa at 50° C. to form an aluminum nitride green sheet. Such laminate was cut into a disc-shaped laminate.

Then, the aluminum nitride green sheet laminate was degreased under vacuum and then baked at a temperature of 1850° C. under nitrogen atmosphere to prepare a planar ceramic body comprising a aluminum nitride-based sintered material having the electrostatic adsorption electrode embedded therein.

Subsequently, the obtained planar ceramic body was ground to adjust the distances between the mounting surface and the adsorption electrode and between the rear side of the planar ceramic body and the adsorption electrode into 300 mm apparently. Thereafter, the mounting surface was wrapped to finish the mounting surface with a surface roughness of 0.2 m in terms of an arithmetical mean roughness Rₐ. At the same time, on the surface opposite to the mounting surface, holes were formed to communicate with the electrostatic adsorption electrode. The holes were inserted by the feeding terminals, and then soldered to obtain a planar ceramic body having an adsorption electrode embedded therein.

A porous SIC body with a diameter of 298 mm diameter and a thickness of 28 mm was impregnated with the aluminum alloy to form a conductive base part comprising 80% by mass of SiC and 20% by mass of an aluminum alloy and having a diameter of 300 mm and a thickness of 30 mm, which has an aluminum alloy layer with a thickness of 1 mm formed on each of lateral sides and the upper and lower surfaces.

Moreover, the wafer supporting member samples Nos. 3 to 7 were prepared by adhering the planar ceramic body made of aluminum nitride to the conductive base part made of aluminum and SiC, using a silicone adhesive having a mixture of aluminum and a silicone resin.

Evaluation was conducted on the adsorption force, the residual absorption force, the temperature variation of the mounting surface and the adhesion state between the planar ceramic body and the conductive base part by mounting the wafer on the mounting surface.

Further, for any one of the samples, the temperature variation of the mounting surface was measured using a thermocouple which is inserted in the holes formed immediately below the center portion of the mounting surface. To the conductive base part, equipped was a water cooling passage to provide cooling water with controlled temperature in a determined amount. After placing the wafer on the mounting surface and heating it by a halogen lamp starting from the upper surface, the temperature variation of the mounting surface was measured after 5 minutes.

Thereafter, the electrostatic adsorption force was determined at room temperature and under vacuum condition. First, the Si wafer of a 1-inch angle was placed on the mounting surface. A voltage of 500 V was applied to both of the wafer W and the conductive base part 2, the Si wafer was pulled out after 1 minute and mounted again after 1 minute, and 50 cycles of adsorption/desorption were repeated. Then, the force required to pull out the Si wafer at the last cycle was measured with a load cell. The measured values were divided by the area of the mounting surface to obtain an electrostatic adsorption force per a unit area. Immediately after that, the Si wafer of 1-inch angle was placed on the mounting surface. A voltage of 500 V was applied for 2 minutes and then the voltage application was stopped. After 3 seconds, the Si wafer was pulled out and the force required to pulling it out was measured with the load cell. Further, the measured value was divided by the area of a 1-inch angle to obtain a residual adsorption force per a unit area.

After completing such measurement, the sample was taken and observed whether the resin layer which is the adhesion side between the planar ceramic body and the conductive base part was delaminated using an ultrasonic flaw detector.

The results are shown in Table 1

TABLE 1

| | | | | | Volume | Thickness | | | Temperature | |
|---|---|---|---|---|---|---|---|---|---|---|
| | | Thickness | | Thickness | resistivity | of | | | variation | |
| | Material | of | Material | of | of | insulating | Residual | | of | |
| | of | insulating | of | insulating | resin | adsorption | adsorption | Occurrence | mounting | Adsorption |
| Sample | insulating | sheet | insulating | layer | layer | layer | force | of | surface | force |
| No. | sheet | (μm) | layer | (μm) | (Ω · cm) | (mm) | (N/m²) | delamination | (° C.) | (N/m²) |
| 1* | Alumina | 300 | Alumina | 10000 | 1 × 10⁷ | 10.3 | 100 | Yes | 10 | 2000 |
| 2 | Alumina | 300 | Alumina | 10000 | 1 × 10⁸ | 10.3 | 120 | No | 7 | 2000 |
| 3 | Aluminum | 300 | Aluminum | 10000 | 2 × 10⁹ | 10.3 | 180 | No | 6 | 25000 |
| | nitride | | nitride | | | | | | | |
| 4 | Aluminum | 500 | Aluminum | 10000 | 5 × 10¹⁰ | 10.5 | 190 | No | 6 | 26000 |
| | nitride | | nitride | | | | | | | |
| 5 | Aluminum | 300 | Aluminum | 10000 | 3 × 10¹² | 10.3 | 170 | No | 6 | 25000 |
| | nitride | | nitride | | | | | | | |
| 6 | Aluminum | 500 | Aluminum | 10000 | 1 × 10¹⁴ | 10.5 | 175 | No | 7 | 25500 |
| | nitride | | nitride | | | | | | | |
| 7* | Aluminum | 300 | Aluminum | 10000 | 8 × 10¹⁶ | 10.3 | 520 | No | 8 | 26000 |
| | nitride | | nitride | | | | | | | |

*means beyond the range of the invention.

The samples Nos. 2 to 6 of the invention each having a volume resistivity of the resin layer in a range of 1×10⁸ to 1×10¹⁴ Ω·cm, exhibited the low temperature variation of the mounting surface of not more than 7° C. and not more than 190 N/m² of the residual adsorption force, as well as excellent characteristics without delamination of the resin layer.

However, the sample No. 1 was undesirable, which exhibited the low volume resistivity of the resin layer of 1×10⁷ Ω·cm and 10° C. of the large temperature variation of the mounting surface. It is understood that it is because of a low content of the adhesive, leading to low adhesion intensity and occurrence of delamination on the resin layer.

The sample No. 7 exhibited the high volume resistivity of the resin layer of 8×10¹⁶ Ω·cm. It was assumed that the residual charges on the mounting surface did not smoothly flow into the conductive base part. Thus, it was proved that since the residual adsorption force was as high as 520 N/m², it was difficult for the residual charges to withdraw from the wafer W in a short time, thereby being undesirable.

### EXAMPLE 2

In the similar way to that of Example 1, a wafer supporting member made of alumina and aluminum nitride was prepared. The aluminum nitride used had various volume resistivities of the materials by varying the amount of the added cerium oxide within a range or 1 to 15% by mass. The samples were prepared, having different volume resistivities by varying the content of Al in the resin layer. In the same manners as in Example 1, the samples were evaluated. Then, the electric resistance value between the mounting surface and the conductive base part was determined for each of the samples.

For the electric resistance value between the mounting surface and the conductive base part, an electrode with a diameter of 10 mm was installed on the mounting surface, and the electric resistance value between the electrode and the conductive base part. The measured electric resistance value was taken as a resistance value between the mounting surface and the conductive substrate as calculated in terms of the area of the mounting surface.

The results of evaluation are shown in Table 2.

TABLE 2

| | | | | | Resistance | | | | |
|---|---|---|---|---|---|---|---|---|---|
| | | | | | between | | | | |
| | | | | | mounting | Thickness | | Temperature | |
| | | Thickness | | Thickness | surface | of | | variation | |
| | Material | of | Material | of | and | insulating | Residual | of | |
| | of | insulating | of | insulating | conductive | adsorption | adsorption | mounting | Adsorption |
| Sample | insulating | sheet | insulating | layer | substrate | layer | force | surface | force |
| No. | sheet | (μm) | layer | (μm) | (Ω) | (mm) | (N/m²) | (° C.) | (N/m²) |
| 21* | Aluminum | 300 | Aluminum | 10000 | 2 × 10⁶ | 10.3 | 30 | 4 | 200 |
| | nitride | | nitride | | | | | | |
| 22 | Aluminum | 500 | Aluminum | 10000 | 1 × 10⁷ | 10.5 | 110 | 4 | 2000 |
| | nitride | | nitride | | | | | | |
| 23 | Aluminum | 300 | Aluminum | 10000 | 5 × 10⁹ | 10.3 | 130 | 4 | 25000 |
| | nitride | | nitride | | | | | | |
| 24 | Aluminum | 500 | Aluminum | 10000 | 3 × 10¹⁰ | 10.5 | 150 | 5 | 26000 |
| | nitride | | nitride | | | | | | |
| 25 | Aluminum | 300 | Aluminum | 10000 | 6 × 10¹¹ | 10.3 | 140 | 4 | 25000 |
| | nitride | | nitride | | | | | | |
| 26 | Alumina | 300 | Alumina | 10000 | 1 × 10¹³ | 10.3 | 155 | 5 | 25500 |
| 27* | Alumina | 300 | Alumina | 10000 | 5 × 10¹⁴ | 10.3 | 400 | 4 | 26000 |

*means beyond the range of the invention.

The samples Nos. 22 to 26 of the invention, each having the electric resistance value between the mounting surface and the conductive base part of 10⁷ to 10¹³, exhibited the high adsorption force of not less than 2000 N/m² and the low residual adsorption force of not more than 155 N/m², and thus it had preferable characteristics.

On the other hand, the sample No. 21 exhibited the low electric resistance value between the mounting surface and the conductive base part of 2×10⁶ n and the low adsorption force of 200 N/m², and thus it was proved that it is difficult to use this sample as a wafer-supporting member.

Further, the sample No. 27 exhibited the high electric resistance value between the mounting surface and the conductive base part of 5×10¹⁴ Ω and the high residual adsorption force of 400 N/m², and thus it was proved that it is difficult to use this sample as a wafer-supporting member.

### EXAMPLE 3

In the similar way to that of Example 2, an electrostatic chuck with varied thickness of the insulating sheet by varying the thickness of the insulating layer was prepared. The samples were evaluated in the same manners as in Example 1.

The results of evaluation are shown in Table 3.

TABLE 3

| | | | | | | Resistance | | | | |
|---|---|---|---|---|---|---|---|---|---|---|
| | | | | | | between | | | | |
| | | | | | Volume | mounting | Thickness | | Temperature | |
| | | Thickness | | Thickness | resistivity | surface | of | | variation | |
| | Material | of | Material | of | of | and | insulating | Residual | of | |
| | of | insulating | of | insulating | resin | conductive | adsorption | adsorption | mounting | Adsorption |
| Sample | insulating | sheet | insulating | layer | layer | substrate | layer | force | surface | force |
| No. | sheet | (μm) | layer | (μm) | (Ω · cm) | (Ω) | (mm) | (N/m²) | (° C.) | (N/m²) |
| 31 | Aluminum | 500 | Aluminum | 10000 | 1 × 10⁸ | 2 × 10⁶ | 10.5 | 150 | 7 | 25000 |
| | nitride | | nitride | | | | | | | |
| 32 | Aluminum | 500 | Aluminum | 8000 | 2 × 10⁸ | 1 × 10⁷ | 8.5 | 90 | 7 | 25000 |
| | nitride | | nitride | | | | | | | |
| 33 | Aluminum | 1000 | Aluminum | 5000 | 1 × 10⁸ | 5 × 10⁹ | 6 | 85 | 6 | 26000 |
| | nitride | | nitride | | | | | | | |
| 34 | Aluminum | 500 | Aluminum | 4000 | 5 × 10⁸ | 3 × 10¹⁰ | 4.5 | 80 | 6 | 25000 |
| | nitride | | nitride | | | | | | | |
| 35 | Aluminum | 1000 | Aluminum | 3000 | 3 × 10⁸ | 6 × 10¹¹ | 4 | 76 | 6 | 25000 |
| | nitride | | nitride | | | | | | | |

The samples Nos. 32 to 35 of the invention having a thickness of the insulating adsorption layer of not more than 10 mm exhibited the low residual adsorption force of not more than 90 N/m², and thereby obtaining more excellent characteristics.

On the other hand, the sample No. 31 exhibited a little higher residual adsorption force of about 150 N/m².

### EXAMPLE 4

In the similar way to that of Example 2, a wafer supporting member as the samples Nos. 41 to 44 was prepared, which has a varied thickness of the insulating adsorption layer by varying each thickness of the insulating sheet and the insulating layer.

A porous SiC body with a diameter of 298 mm and a thickness of 28 mm was impregnated with the aluminum alloy to form a conductive base part comprising 80% by mass of Sic and 20% by mass of an aluminum alloy and having a diameter of 300 mm and a thickness of 30 mm, which has an aluminum alloy layer with a thickness of 1 mm formed on each of lateral bides and the upper and lower surfaces an the upper surface, an insulating layer made of amorphous ceramics was formed in a thickness of 5 to 50 μm. Then, by gold-plating thereon, an adsorption electrode having a thickness of 1 μm was formed. Holes passing through the conductive base part were formed and feeding terminals were installed through insulating tubes. Further, on the upper surface, an alumina film with a thickness of 5 to 50 μm as amorphous ceramics was also formed. Then, the film-formed side was ground to be made into a mounting surface, thereby obtaining the samples Nos. 45 to 47.

The samples were evaluated in the same manners as in Example 1.

For evaluations of the dielectric breakdown, it was evaluated whether dielectric breakdown of the insulating sheet occurred or not by applying a voltage or 3 kV to the adsorption electrode.

The results are shown in Table 4.

TABLE 4

| | | | | | Thickness | | Temperature | | |
|---|---|---|---|---|---|---|---|---|---|
| | | Thickness | | Thickness | of | | variation | Dielectric | |
| | Material | of | Material | of | insulating | Residual | of | breakdown | |
| | of | insulating | of | insulating | adsorption | adsorption | mounting | of | Adsorption |
| Sample | insulating | sheet | insulating | layer | layer | force | surface | insulating | force |
| No. | sheet | (μm) | layer | (μm) | (mm) | (N/m²) | (° C.) | sheet | (N/m²) |
| 41 | Aluminum | 500 | Aluminum | 2000 | 2.5 | 75 | 6 | No | 25000 |
| | nitride | | nitride | | | | | | |
| 42 | Aluminum | 500 | Aluminum | 1000 | 1.5 | 60 | 4 | No | 25000 |
| | nitride | | nitride | | | | | | |
| 43 | Alumina | 500 | alumina | 500 | 1 | 55 | 4 | No | 25000 |
| 44 | Alumina | 300 | alumina | 300 | 0.6 | 47 | 3 | No | 25000 |
| 45 | Amorphous | 50 | Amorphous | 50 | 0.1 | 10 | 3 | No | 25000 |
| | alumina | | alumina | | | | | | |
| 46 | Amorphous | 15 | Amorphous | 5 | 0.02 | 10 | 3 | no | 25000 |
| | alumina | | alumina | | | | | | |
| 47 | Amorphous | 5 | Amorphous | 5 | 0.01 | 10 | 3 | Yes | 20000 |
| | alumina | | alumina | | | | | | |

The samples Nos. 42 to 46 of the invention having thickness of the insulating adsorption layer of 20 μm to 2 mm exhibited the low temperature variation of not more than 4° C. in the mounting surface, the low residual adsorption characteristics of not more than 60 N/m² and no dielectric breakdown, thereby obtaining excellent characteristics.

On the other hand, the sample No. 41 having a thickness of the insulating adsorption layer of 2.5 mm exhibited a little higher residual adsorption force of 75 N/m².

Further, for the sample No. 47 having a low thickness of the insulating adsorption layer of 10 μm, it was observed that the insulating sheet was broke, and thus this sample cannot be used as the electrostatic chuck.

### EXAMPLE 5

In the similar way to that of Example 1, a wafer supporting member was prepared. Further, as the resin layer, any one selected from the group made of a silicone resin, a polyimide resin, a polyamide resin, an epoxy resin and a urethane resin was used.

The samples were evaluated in the same manners as in Example 1.

The results are shown in Table 5

TABLE 5

| | | | | | | Thickness | | Temperature | Occurrence | |
|---|---|---|---|---|---|---|---|---|---|---|
| | | Thickness | | Thickness | Main | of | | variation | of | |
| | Material | of | Material | of | component | insulating | Residual | of | delamination | |
| | of | insulating | of | insulating | of | adsorption | adsorption | mounting | of | Adsorption |
| Sample | insulating | sheet | insulating | layer | resin | layer | force | surface | resin | force |
| No. | sheet | (μm) | layer | (μm) | layer | (mm) | (N/m²) | (° C.) | layer | (N/m²) |
| 51 | Aluminum | 500 | Aluminum | 1000 | Silicone | 1.5 | 65 | 4 | No | 25000 |
| | nitride | | nitride | | resin | | | | | |
| 52 | Alumina | 500 | Alumina | 500 | Polyimide | 1 | 50 | 4 | No | 25000 |
| | | | | | resin | | | | | |
| 53 | Alumina | 300 | Alumina | 300 | Polyamide | 0.6 | 40 | 3 | No | 25000 |
| | | | | | resin | | | | | |
| 54 | Alumina | 300 | Alumina | 300 | Epoxy | 0.6 | 40 | 3 | No | 25000 |
| | | | | | resin | | | | | |
| 55 | Alumina | 300 | Alumina | 300 | Urethane | 0.6 | 40 | 3 | Yes | 20000 |
| | | | | | resin | | | | | |

The samples Nos. 51 to 54 of the invention having the resin layer made of any one selected from a silicone resin, a polyimide resin, a polyamide resin and an epoxy resin exhibited excellent characteristics without delamination of the resin layer.

On the other hand, the sample No. 55 which has the resin layer comprising a urethane resin showed delamination of the resin layer, and thus this sample was proved to be not desirable.

### EXAMPLE 6

A resin layer was prepared using a silicone resin and a polyimide rosin as main components for the resin layer and adding carbon powders and metal powders such as Al, Pt and Au as conductive particles. Further, in the same manners as in Example 4, a wafer supporting member was prepared.

The samples were evaluated in the same manners as in Example 1.

TABLE 6

| | | | | | | Material | Content | | | | | | |
|---|---|---|---|---|---|---|---|---|---|---|---|---|---|
| | | Thick- | | Thick- | | of | of | | | | | Temper- | |
| | | ness | | ness | Main | conduc- | conductive | Thick- | Thickness | | Occurrence | ature | Ad- |
| | | of | | of | compo- | tive | particles | ness | of | | of | variation | sorp- |
| | Material | insu- | Material | insu- | nent | particles | in | of | insulating | Residual | delamination | of | tion |
| Sam- | of | lating | of | lating | of | in | resin | resin | adsorption | adsorption | of | mounting | force |
| ple | insulating | sheet | insulating | layer | resin | resin | layer | layer | layer | force | resin | surface | (N/ |
| No. | sheet | (μm) | layer | (μm) | layer | layer | (%) | (mm) | (mm) | (N/m²) | layer | (° C.) | m²) |
| 61 | Aluminum | 500 | Aluminum | 1000 | Silicone | C | 0.005 | 0.05 | 1.5 | 185 | No | 1 | 25 |
| | nitride | | nitride | | resin | | | | | | | | |
| 62 | Aluminum | 500 | Aluminum | 1000 | Silicone | C | 0.01 | 0.0005 | 1.5 | 110 | Yes | 7 | 25 |
| | nitride | | nitride | | resin | | | | | | | | |
| 63 | alumina | 500 | Alumina | 500 | Silicone | C | 0.01 | 0.001 | 1 | 40 | No | 1 | 25 |
| | | | | | resin | | | | | | | | |
| 64 | Alumina | 300 | Alumina | 300 | Silicone | Al | 0.1 | 0.05 | 0.6 | 35 | No | 1 | 25 |
| | | | | | resin | | | | | | | | |
| 65 | Alumina | 300 | Alumina | 300 | Polyimide | Al | 5 | 0.5 | 0.6 | 35 | No | 2 | 25 |
| | | | | | resin | | | | | | | | |
| 66 | Alumina | 300 | Alumina | 300 | Silicone | Al | 30 | 1 | 0.6 | 40 | No | 2 | 25 |
| | | | | | resin | | | | | | | | |
| 67 | Alumina | 300 | Alumina | 300 | Polyimide | Al | 30 | 2 | 0.6 | 135 | No | 3 | 25 |
| | | | | | resin | | | | | | | | |
| 68 | Alumina | 300 | Alumina | 300 | Polyimide | Al | 35 | 0.05 | 0.6 | 125 | Yes | 8 | 25 |
| | | | | | resin | | | | | | | | |
| 69 | Amor- | 100 | Amor- | 100 | Polyimide | Pt | 4 | 0.05 | 0.2 | 30 | No | 3 | 25 |
| | phous | | phous | | resin | | | | | | | | |
| | alumina | | alumina | | | | | | | | | | |
| 70 | Alumina | 300 | Alumina | 300 | Polyimide | Au | 5 | 0.05 | 0.6 | 35 | no | 3 | 20 |
| | | | | | resin | | | | | | | | |

The samples Nos. 61 to 70 of the invention with the resin layer containing the conductive particles exhibited the residual adsorption force of not more than 125 N/m² and the adsorption force of not less than 20 N/m² and thus it was proved that they can be used.

Further, the samples Nos. 63 to 67, 69 and 70 containing 0.01 to 30% by volume of the conductive particles in the resin layer exhibited the residual adsorption force of not more than 135 N/m², and thus these samples were proved to and excellent characteristics without delamination of the resin layer.

On the other hand, the sample No. 61 containing 0.005% by volume of the conductive particles in the resin layer exhibited the high residual adsorption force of 185 N/m² and occurrence of delamination of the resin layer, and thus it is not desirable.

For the sample No. 68, the content of the conductive particles of the resin layer was as high as more than 30% by volume, and thus the delamination of the resin layer occurred during use. As a result, the temperature variation was as high as 8° C.

The samples Nos. 63 to 66, 69 and 70 comprising the resin layer having a thickness of 0.001 mm to 1 mm exhibited The residual adsorption force of not more than 40 N/m², and more excellent characteristics.

### EXAMPLE 7

In the same manners as in Example 4 except for changing the thickness of the insulating sheet, samples were prepared. The samples were evaluated in the same manners as in Example 4.

Further, the resin layer having a volume resistivity of 10¹² Ω·cm was used.

For evaluations of the plasma resistance, the wafer supporting member was equipped with a cover ring at lateral side to cover the side. With no wafer W mounted on the mounting surface, a high-frequency electric power of 2 kW was supplied between the opposite electrode on the upper surface or the mounting surface and the conductive base part 2 at a degree of vacuum of 4 Pa while flowing Cl₂ as a halogen gas into the member at a flow rate of 60 sccm. By this, plasma was generated between the opposite electrode and the mounting, surface and thus both sides were exposed to the mounting surface for 100 hours. Thereafter, the state of the insulating sheet was observed to investigate the corrosion of the insulating sheet and thus the exposure of the conductive base part, the non-occurrence of unevenness on surface of the mounting surface, and the adhesion state between the planar ceramic body and the conductive base part. In addition, the difference between the temperature of the mounting surface before generation of plasma and the temperature of the mounting surface 1 hour after generation of plasma was evaluated as a temperature variation of the mounting surface.

The results are shown in Table 7.

TABLE 7

| | | | | | | | Occurrence | | | | |
|---|---|---|---|---|---|---|---|---|---|---|---|
| | | | | | Thickness | Temperature | of | Occurrence | | | |
| | | Thickness | | Thickness | of | variation | dielectric | of | | | Residual |
| | Material | of | Material | of | insulating | of | breakdown | delamination | | Adsor- | Ad- |
| | of | insulating | of | insulating | adsorption | mouting | of | of | | ption | sorption |
| Sample | insulating | sheet | insulating | layer | layer | part | insulating | resin | Plasma- | force | force |
| No. | sheet | (μm) | layer | (μm) | (μm) | (° C.) | sheet | layer | resistance | (N/m²) | (N/m²) |
| 71 | Amorphous | 5 | Amorphous | 5 | 10 | 0.4 | Yes | No | Corrosion | — | — |
| | alumina | | alumina | | | | | | | | |
| 72 | Amorphous | 15 | Amorphous | 5 | 20 | 0.5 | No | No | Good | 250000 | 10 |
| | alumina | | alumina | | | | | | | | |
| 73 | Amorphous | 50 | Amorphous | 50 | 100 | 0.5 | No | no | Good | 10000 | 10 |
| | alumina | | alumina | | | | | | | | |
| 74 | Amorphous | 100 | Amorphous | 100 | 200 | 0.6 | no | No | Good | 2500 | 10 |
| | alumina | | alumina | | | | | | | | |
| 75 | Amorphous | 200 | Amorphous | 200 | 400 | 0.6 | No | No | Good | 2000 | 15 |
| | alumina | | alumina | | | | | | | | |
| 76 | Thermal | 100 | Amorphous | 100 | 200 | 2 | No | No | Corrosion | 2000 | 120 |
| | coating | | alumina | | | | | | | | |
| 77 | Positive | 100 | Amorphous | 110 | 210 | 1 | No | No | A | 3500 | 400 |
| | oxidation | | alumina | | | | | | little | | |
| | film + | | | | | | | | corrosion | | |
| | amorphous | | | | | | | | | | |
| | film | | | | | | | | | | |
| 78 | Alumina | 300 | alumina | 300 | 600 | 1 | No | No | Good | 1000 | 15 |
| 79 | Aluminum | 500 | Aluminum | 500 | 1000 | 4 | No | No | Good | 2000 | 20 |
| | nitride | | nitride | | | | | | | | |
| 80 | Aluminum | 1000 | Aluminum | 1000 | 2000 | 5 | No | No | Good | 2000 | 20 |
| | nitride | | nitride | | | | | | | | |
| 81 | Aluminum | 2000 | Aluminum | 2000 | 4000 | 50 | No | No | Good | 1000 | 300 |
| | nitride | | nitride | | | | | | | | |

The samples Nos. 72 to 75 of the invention containing the insulating sheet having a thickness of 15 μm to 200 μm exhibited the low temperature variation of less than 1° C. on the mounting surface without occurrence of dielectric breakdown and cracks of the insulating sheet. Thus, it was found that they have good plasma-resistance and no delamination of the resin layer, and thus have excellent characteristics.

Meanwhile, the sample No. 71 containing the insulating sheet made of the amorphous ceramics having very low thickness did not exhibit cracks or delamination thereof, but the conductive base part was exposed due to corrosion by plasma and thus it could not used for a long time. The sample No. 81 had a high total thickness of the insulating sheet and the insulating layer of 4000 μm and a large temperature rise of the mounting surface or 7° C. due to heating by plasma. Accordingly, it could not be used when the wafer W was subject to a treatment under strictly narrow temperature range, and thus it could only use an insulating sheet which was treated under a gentle condition.

Further, the samples Nos. 72 to 74 containing the insulating sheet having a thickness of 10 μm to 100 μm exhibited the high adsorption force of not less than 2500 N/m² and the residual adsorption force of not more than 10 Pa, and thus it was found that it exhibited more excellent characteristics.

The samples Nos. 78 to 80 containing the insulating sheet made of a sintered material had the adsorption force of not less than 1000 N/m², the low residual adsorption force of not more than 20 N/m² and good plasma-resistance, and thus it was found that it had preferable characteristics.

On the other hand, the sample No. 77 containing the insulating sheet made of amorphous alumina on the aluminum positive oxidation film, had preferably high adsorption force of 3500 N/m², but it had a little higher residual adsorption force of 400 N/m². It is understood that such a little higher residual adsorption force is caused by difference of the volume resistivities between the positive oxidation film and the amorphous aluminum oxidation film.

### EXAMPLE 8

Next, for the conductive base part 2, a composite material having a diameter of 300 mm as described in Example 1 was used and as the insulating sheet 5, amorphous aluminum oxide was used. Further, the film forming conditions were changed to prepare a film with the amount of argon correspondingly changed, for which occurrence of delamination or cracks was evaluated.

Delamination and cracks were evaluated before and after repeating 500 times the plasma cycles, in which plasma was generated on the upper surface of the wafer supporting member for 10 minutes as described in Example 7, and then the generation was stopped for 10 minutes.

TABLE 8

| | | | Occurrence of |
|---|---|---|---|
| | | Occurrence of | dielectric |
| Sample | Amount of Ar | crack or | breakdown of |
| No. | (% by atom) | delamination | insulating sheet |
| 82 | 0.5 | Yes | — |
| 83 | 1 | No | No |
| 84 | 3 | No | No |
| 85 | 6 | No | No |
| 86 | 10 | No | No |

For the sample No. 82 containing a low amount of argon 5% by atom, cracks occurred on the insulating sheet.

However, the samples Nos. 83 to 86 of the invention containing 1 to 10% by atom of argon as a rare gas element exhibited neither cracks on the insulating sheet nor dielectric breakdown, and thus it was found that the amount of the rare gas element is preferably 1 to 10% by atom.

Next, for the conductive base part 2, those having a diameter of 300 mm and a thickness of 30 mm as described in Example 1 was used, and as the insulating sheet 5, amorphous aluminum oxide was used. Further, the film-forming conditions were changed to form a film with the Vickers hardness of the insulating sheet 5 correspondingly changed, for which occurrence of delamination or cracks was evaluated.

On the conductive base part 2, the insulating sheet 5 having a thickness of 30 μm was provided, which was made of the amorphous ceramics of aluminum oxide under the various film-forming conditions.

The Vickers hardness was determined by applying a 0.98 N load for 15 seconds corresponding to the hardness symbol HV 0.1 of JIS R1610, and then measuring the size of the impressed product.

TABLE 9

| | | Occurrence of | Occurrence of |
|---|---|---|---|
| Sample | | cracks or | dielectric breakdown |
| No. | Hardness (HV) | delamination | of insulating sheet |
| 91 | 400 | No | Yes |
| 92 | 500 | No | No |
| 93 | 750 | No | No |
| 94 | 1000 | No | No |
| 95 | 1200 | Yes | — |

The sample No. 91 having a low Vickers hardness of 400 HV 0.1 did not exhibited occurrence of cracks, but dielectric breakdown. It is understood that this is because too low hardness caused scratches on the insulating sheet, thereby leading to occurrence of dielectric breakdown. On the other hand, the sample No. 95 having a high Vickers hardness of 1200 HV 0.1 exhibited occurrence of cracks on the insulating sheet. It is understood that this is because the insulating sheet cannot reduce inner stress.

Accordingly, it was found that the Vickers hardness is preferably 500 to 1000 HV 0.1 as in the samples Nos. 92 to 94.

### EXAMPLE 9

The samples Nos. 101 to 104 containing any one selected from aluminum oxide, yttrium oxide, yttrium aluminum oxide and cerium oxide in stead of the material of the insulating sheet made of the amorphous ceramics were compared with the sample No. 105 containing multi-crystalline alumina as a comparative example for the etching rates of the insulating sheet by exposing both of them to plasma.

For the evaluation method, cover rings were provided on the peripheral Surface and the lateral side of the wafer supporting member to cover the portions having no insulating sheet adhered thereto and plasma was irradiated on the surface of the insulating sheet. The conditions of plasma are such that a high-frequency electric power of 2 kW was supplied between the opposite electrode on the upper surface of the mounting surface and the conductive base part 2 at a degree of vacuum of 4 Pa while flowing Cl₂ as a halogen gas into the member at a flow rate of 60 sccm. By this, plasma was generated between the opposite electrode and the mounting surface and thus both sides were exposed to the mounting surface for 2 hours. From the wear thickness of the insulating sheet by etching, the etching rate was calculated. The wear thickness of each film was divided by the wear thickness of the sintered alumina to obtain an etching rate. The results are shown in Table 10.

TABLE 10

| Sample No. | Material | Etching rate |
|---|---|---|
| 101 | Aluminum oxide | 0.7 |
| 102 | Yttrium oxide | 0.2 |
| 103 | Yttrium Aluminum | 0.3 |
| | oxide | |
| 104 | Cerium oxide | 0.3 |
| 105 | Aluminum oxide | 1 |
| | sintered body | |

As compared to the etching rate of the sample No. 105 containing multi-crystalline alumina, the sample No. 101, i.e., the aluminum oxide film containing the amorphous ceramics had a low etching rate of 0.7. The insulating sheets 5 made of the amorphous ceramics such as yttrium oxide, yttrium aluminum oxide and cerium oxide, had etching rates of 0.2, 0.3 and 0.3, respectively. Thus, it was found that the insulating sheet 5 has excellent plasma-resistance.

### EXAMPLE 10

An aluminum oxide film made of the amorphous ceramics was formed on the upper surface of the conductive base part 2 having a diameter of 300 mm and a thickness of 30 mm which formed an aluminum alloy layer with a thickness of 1 mm on the lateral sides and the upper and lower surface thereof by changing the content of SiC having a diameter of 298 mm and a thickness of 28 mm into 50 to 90% by mass (the rest was an aluminum alloy). For this, a test for the temperature cycle of −20° C. to 200° C. was carried out. However, as a result, occurrence of cracks on the amorphous aluminum oxide film was not observed.

### EXAMPLE 11

A porous SiC body with a diameter of 298 mL and a thickness of 28 mm, comprising 80% by mass of SiC and 20% by mass of an aluminum alloy was impregnated with the aluminum alloy to form a conductive base part 2 having a diameter of 300 mm and a thickness of 30 mm, which has an aluminum alloy layer with a thickness of 1 mm formed on each of lateral sides and the upper and lower surfaces. Then, an amorphous ceramic aluminum oxide film was formed on the upper surface of the conductive base part 2 and an aluminum positive oxidation film as a plasma-resistant protective film was formed on other portions of the base part 2 while alumina thermal film was formed, thereby preparing a wafer supporting member 1, for which ad temperature cycle test of 20° C. to 200° C. was carried out, and as a result, occurrence of cracks was not observed on the protective film.

### Second Embodiment

Hereinafter, a second embodiment of the invention will be described in detail:

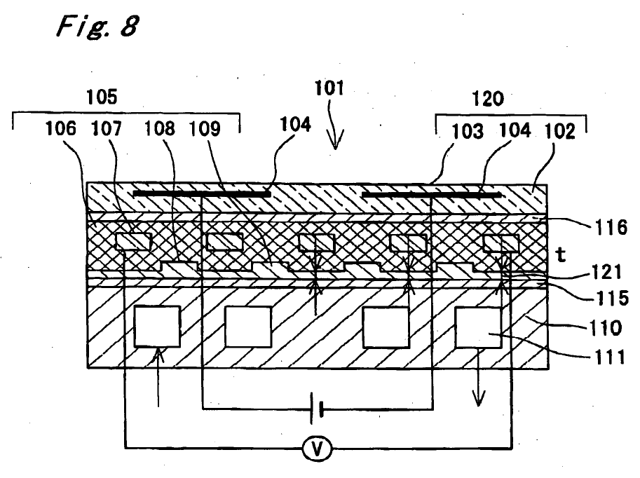

FIG. 8 illustrates one example of the wafer supporting member 101 according to the invention.

The wafer supporting member 101 includes a supporting part 120 having one main surface of a disc-shaped planar body 102 as a mounting surface 103 for mounting a wafer W and a pair of the electrostatic adsorption electrodes 104 embedded in the mounting surface 103 of the planar body 102, and a heater part 105 having a heater 107 embedded in an insulating resin 106 filled with a resin 109 having the insulating resin 106 filled with a resin 109 having composition different from the resin 116, wherein the heater part 105 is interposed between the supporting part 120 and the conductive base part 110 using adhesive layers 116 and 115, respectively.

The conductive base part 110 consists of the conductive materials including, for example, the metal materials such as aluminum and cemented carbide or composite materials such as said metal materials and the ceramic materials, and may function as an electrode for generating plasma. The conductive base part 1b has a passage 111 inside, through which a cooling medium such as a cooling gas and a cooling water flows in order to adjust the temperature of the wafer W placed on the supporting part 120 into a predetermined temperature.

For the planar body 102 constructing the supporting part 120, a sintered body such as an alumina-based sintered body, a silicon nitride-based sintered body, an aluminum nitride-based sintered body, a yttrium-aluminum-garnet-based sintered body (hereinafter, referred to as ‘a YAG sintered body’), and a single-crystalline alumina (sappier) can be used. Among them, the aluminum nitride-based sintered body has at least 50 W/(m·K), or even at least 100 W/(m·K) of thermal conductivity, and thus is more preferable to reduce the temperature difference the inside of the wafer W.

The wafer supporting member 101 can be vacuum sealed by forming the heater 107 using a metal foil or a metal wire and inserting the insulating resin 106 in the form of the sheet film having a constant thickness into the upper and lower surfaces thereof. Unevenness equal to the thickness of the heater 107 is formed according to the shapes of the heater 107 on the upper and lower surfaces of the insulating resin 106 in the heater part 105. Herein, in order to improve evenness, the unevenness is preferably removed to obtain a flat form, however there is a concern that the heater 107 is exposed or the insulating resin 106 partially gets thinner, thus losing the insulating property when cutting the convex portions. Accordingly, it is difficult to cut the insulating resin 106 into a flat form. In consideration of this problem, it is preferable to form the heater part 105, wherein the concave portion 108 of the unevenness is filled with another resin having different composition from the insulating resin 106. Herein, for the resin for filling the concave portions 108, a liquid is preferably filled for solidifying the resin to prevent voids. If the resin having the same composition as for the Insulating resin 106 is filled in the concave portions 108, there may be a problem that since it swells the insulating resin and thus adversely affects the function of the heater 107. Therefore, it is preferable to fill the resin 109 having composition different from that of the insulating resin 106.

More particularly, the resin 109 includes preferably a thermo-curing resin such as an adhesive. After pouring the resin 109 to fill the concave portions 108, sufficiently de-foaming the resin to remove foams and heating and curing the resin, the surface of the treated resin is ground using a rotary grinder, a surface grinder or the like to obtain a heater part 105 having a flat and smooth surface of the resin 109. Herein, the surface roughness of the grinding surface is preferably in a range of 0.2 to 2.0 μm in terms of an arithmetical mean roughness Ra according to a JIS B0601-1991 standard with less than 0.2 μm Ra, no anchor effect can be expected to rigidly attach the surface of the resin 9 to the upper surface of the conductive base part 110 since fine recesses allowing the adhesive to be penetrated is removed. Further, it requires time for grinding so as to reduce the roughness to 0.2 μm Ra or less, thereby causing a disadvantage of production efficiency with more than 0.2 μm Ra, there is a concern that cracks are generated inside the resin 109, thus partial detachment of the resin 109 is caused.

The upper surface of the heater part 105 and the lower surface of the supporting part 120, and the lower surface of the heater part 105 and the upper surface of the conductive base part 110 can be uniformly in contact, so that the heater 107 made of a metal foil generates heat by flowing electric current into the heater 107 and evenly transfers the generated heat over the entire surface of the supporting part 120.

Hereinabove, the concave portions 108 was described for the case wherein it is located on the side of the conductive base part 110. However, it is a matter of course that the same effect can be accomplished by filling the resin 109 having composition different from that of the insulating resin 106 into the concave portions 108 when the concave portions 108 are located on the side of the supporting part 120.

Further, by flowing electric current to the electrostatic adsorption electrodes 4 equipped in the planar body 102 to construct the supporting part 120, the electrostatic adsorption force was expressed and the wafer W was adsorption-secured to the mounting surface 103 which enhanced the thermal conductivity between the mounting surface 103 and the wafer W so that the wafer W is heated efficiently.

Further, regarding the heater part 105 having the heater 107 embedded in the insulating resin 106, it is preferable to have polyimide resin as the insulating resin 106. The polymide resin has an excellent heat-resistance and a favorable electric-insulation so that a thickness of the resin may be preferably reduced. In addition, it is much preferable that the heater 107 can be easily embedded into the insulating resin 106 by thermocompression. Even though the polyimide resin was used to embed the heater 107, its thickness was only in a range of 0.05 mm to 0.5 mm. Therefore, because the thickness can be reduced, it was possible to increase uniformity of the wafer W even if the polyimide resin had relatively low thermal conductivity.

Further, in order to evenly transfer the heat generated from the heater 107 to the wafer W, it is preferable to have the identical thermal conductivity of the insulating resin 106 to the other resin 109 having the different composition, which filled the concave portions 108 on the surface of the resin 106. In addition, the term ‘identical to’ in the invention is defined as to having the thermal conductivity of the resin 106 in a range of about 0.8 to 1.2 times the thermal conductivity of the resin 109.

When the thermal conductivity of the resin 109 exceeds 1.2 times the thermal conductivity of the resin 106, it is not preferable because the heat generated from the heater 107 is promptly transferred, and the temperature on the thick portion of the resin 109 is increased. On the other hand, when the thermal conductivity of the resin 109 for filling the concave portion 108 on the heater surface is less than about 0.8 times the thermal conductivity of the resin 106, it is not preferable because the heat transfer between the heaters 107 is delayed which result in increase in the temperature deviation at the mounting surface 103 of the supporting part 120. The thermal conductivity of the resin 109 is at a preferable range of 0.9 to 1.1 times the thermal conductivity of the resin 106.

A method for controlling the thermal conductivity of the resin 109 includes adding a metal powder or a ceramic powder in a range of 0.1 to 10% by mass to the resin 109 to control the thermal conductivity so that the thermal conductivity is substantially the same to the thermal conductivity of the resin 106.

At this time, the resin 109 filled in the concave portions 108 include preferably, an epoxy resin or a silicon resin. The adhesive composed of such resin has less viscosity, and can be tightly filled into the concave portions 108 without penetration of air by applying it on the concave portions 108 of the heater surface for de-foaming.

Especially, the epoxy resin having a sufficient hardness can be obtained when heat-cured, therefore the surface of the resin 109 is ground using the rotary type or multi-functional grinders, thereby adjusting the thickness of the heater part 105 easily and conducting the finishing process on a smooth surface is possible simultaneously. Therefore, when the supporting part 120 or the conductive base part 110 is attached thereto, it is occurred in the front portion of, each member with excellent precision.

Further, the resin of the heater part 105 has the preferable average thickness t in a range of 0.01 to 1 mm. Such average resin thickness is calculated by measuring the thickness at the center portion of the heater part 105 and the two points in the outer circumference and the two, points between the center portion and the outer circumference of the resin, then the average value of the total thickness at five points were calculated to the average thickness t. When the average thickness t is less than 0.01 mm, the electrical short-circuit is occurred in between the heater 107 and the conductive base part which may lead to dielectric breakdown. When the average thickness t exceeds 1 mm, the heat generated from the heater 107 cannot be transferred rapidly to the supporting part 120 or the conductive base part 110, thereby it is not preferable due to having difficulties in the prompt cooling or the uniformly heating of the wafer W. More preferable thickness is in a range of 0.1 to 0.5 mm.

Additionally, the average thickness is defined as an average value of the measurements at five points in a distance from upper surface of the heater 107 in the heater part 105 to outer surface of the heater part 105.

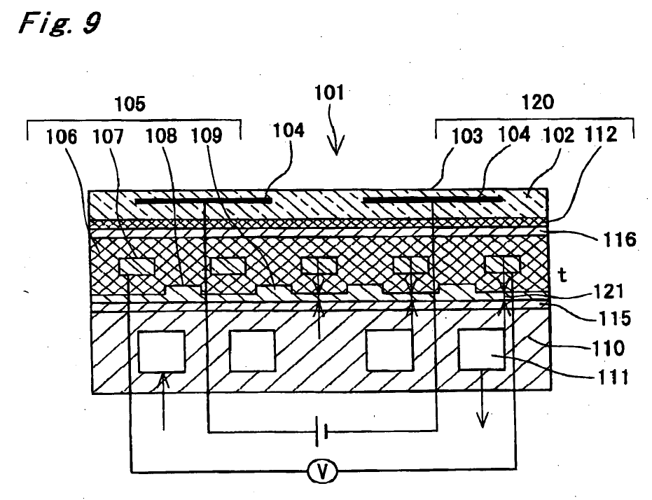

As illustrated in FIG. 9, the supporting part 120 is formed by inserting a heat-uniformity planar body 112 made of ceramics having thermal conductivity higher than that of the planar body 102 into lower surface of the planar body 102 and integrating them. Such construction allows the planar body 102 or the mounting surface 103 of the heat-uniformity planer body 112 to have, but partially, the thermal conductivity of 50 to 419 W/(m·K) in a parallel direction. As a result, the temperature variation may be lowered and the heat-uniformity may be increased inside the wafer W surface.

Accordingly, the thermal conductivity in the parallel direction to the mounting surface 103 of the planar body 102 or the heat-uniformity planar body 102 is preferably in a range of 50 to 419 W/(m·K). This is because when the thermal conductivity in the parallel direction to the mounting surface 103 of the planar body 102 or the heat-uniformity planar body 102 is less than 50 W/(m·K), the time in needed until the temperature becomes constantly maintained in the direction parallel to the mounting surface 103 during that the heat generated from the heater 107 is transferred to the mounting surface 103, which result in increase in the temperature deviation as well as the time delay from altering the temperature of the wafer W.

On the contrary, when the thermal conductivity in the direction parallel to the mounting surface 103 of the planar body 102 or the heat uniformity planar body 112 exceeds 419 W/(m·K), it is difficult to provide industrially available materials at a low cost since the high frequency materials such as silver cannot be used.

As illustrated in FIGS. 8 and 9, the adhesive layers 115 and 116 for the wafer supporting member 101 of the invention has the preferable thickness in a range of 0.01 mm to 1 mm as an average value. When such average value is less than 0.01 mm, the portion not having the adhesive layers 115 and 116 may occur easily, so that the heater 107 and the conductive bare part 110 of the heater 107 and the adsorption electrodes 104 may form portions having thermal-insulation. When the average thickness exceeds 1 mm, the heat from the heater 7 cannot be rapidly transferred to the supporting part 120 or the conductive base part 110. Thus, it is difficult to rapidly refrigerate and/or uniformly-heat the wafer W. The thickness in a range of 0.05 mm to 0.8 mm is more preferred.

Meanwhile, since the stress caused by the precise difference in the thermal expansion coefficient can be relived between the supporting part 120 and a heater 105, or the heater 105 and the conductive base part 110, the adhesive layers 115 and 116 are preferably made of resilient resins such as a silicone resin. However, by controlling the thermal expansions coefficient a little of the support part 120, the heater part 105 and the conductive base part 110, the adhesive layers 115 and 116 can be substituted by other resins including an insulating resin 106 consisting the heater part 105 and the other resin 109 different from the insulating resin 106.

In order to efficiently transfer heat generated from the heater part 105 to respective parts uniformly, the thickness deviation of the adhesive layers 115 and 116 composed of the adhesive is preferably uniformly adjusted within 50 μm.

Further, in the wafer supporting member 101 of the invention, the adhesive layers 115 and 116 are preferably formed of multi-times layered pattern. Such multi-times layered adhesive layers 115 and 116 can prevent large foams from remaining in the adhesive layers. When the adhesive layers 115 and 116 are formed by applying the adhesive only once, large foams may be generated in the same thickness as the adhesive layers, remaining in the adhesive layers at times. Accordingly, by forming the adhesive layers 115 and 116 in a multi-layer, the size of the generated foams can be reduce to less than the thickness of the adhesive layer in a single applying. Therefore, having no large foams in the adhesive layers 115 and 116, the heat-uniformity of the wafer W may be increased.

In addition, the adhesive layers 115 and 116 are preferably formed Separately in multi-times using the screen-printing method. In the screen-printing method, the thickness may be controlled easily and the unevenness may be reduced, due to having the coating thickness substantially the same as the thickness of the screen. Thus, even though the multi-times layered adhesive layers are individually formed multi-times, the uneven values can be greatly reduced. The adhesive layer is solidified at every coating, and by the repetition of applying/solidifying the adhesive layers, the thickness can be gradually increased.

A method fox producing a wafer in the invention supporting member 101 comprises adhering a supporting part 120, a heater part 105 and a conductive base 110 to a water supporting member through each adhesive layer 115 and 116, wherein the heater part 120 and the conductive base part 110 and/or the conductive base part 110 containing supporting part 120 and the heater part 105 are placed in an adhesion container where the inner pressure is decreased, followed by conducting a press-adhesion thereto. Thereafter, the inner pressure of the container is preferably increased.

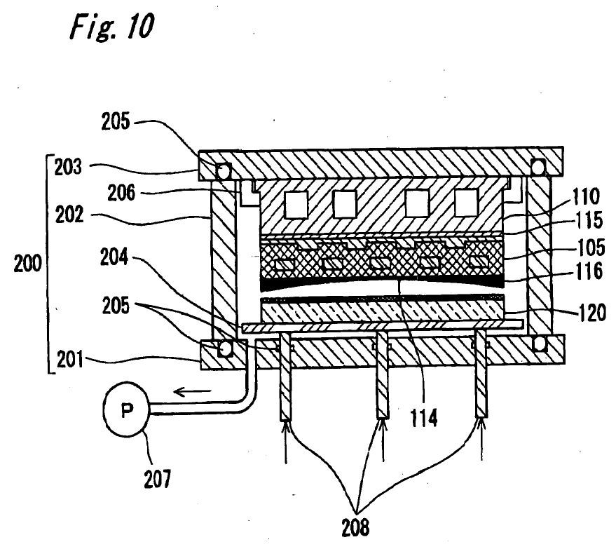

The adhesion container of the invention illustrated in FIG. 10 has the preferable minimum size for a subject to be attached to enter easily and conduct an adhesion process. By reducing vacuum pressure of the container less than 5 times of volume of the subject, it is possible to reduce the vacuum pressure for short time to result in high production efficiency. Further, by having such volume, it can stop and/or inhibit deterioration of the adhesive caused by the vaporizing solvent in the adhesive. Consequently, the effect of the adhesive deterioration is inhibited as low as possible.

The adhesion container of the invention as illustrated in FIG. 10, includes a floor panel 201, a side wall 202 and a cover 203 as the main members, in which the conductive base part 10 is secured using the fixture 206, and the supporting part 120 may be pressed by the wafer supporting member inside the supporting bar 208.

Using such adhesion container, adhesion can be conducted without air (foams) remaining on the adhesion surface. Further, under vacuum condition in the container, the size of pores can be reduced even when air flows into the adhesive layer.

FIG. 10 illustrates orders of adhesion for the wafer supporting member 101 according to the present invention. Herein, described was the adhesion of the conductive base part 110 and the heater part 105 as an example. The adhesion of the conductive base part having the heater part, and the supporting part will also follow the same orders.

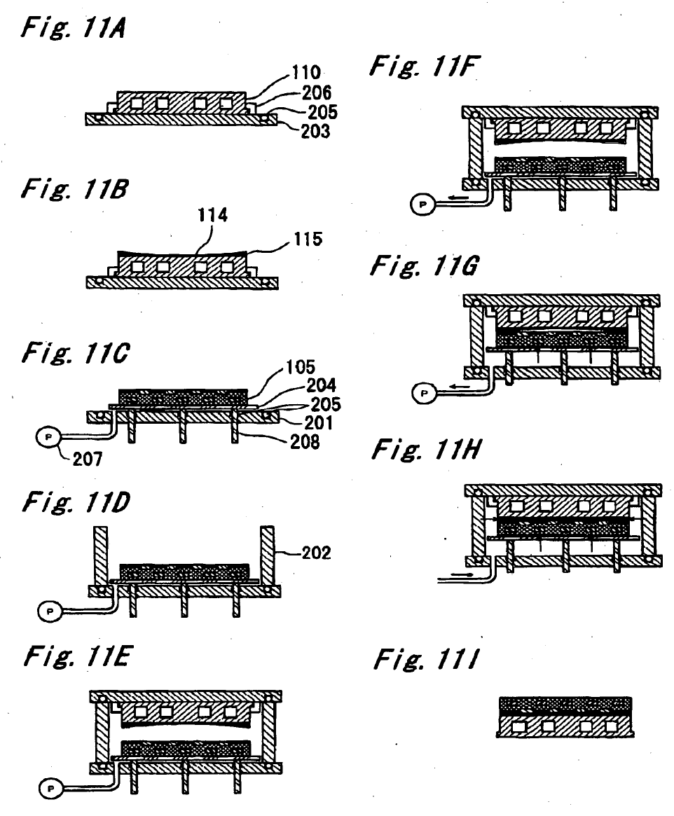

The adhesion is carried out in the following orders a), b), c), d), e), f), g), h) respective to FIGS. 11 a) to h).

a) The conductive base part 110 is secured on a cover 203 using a conductive base part fixture jig 206.

b) The adhesive agent 115 is applied to the adhesion surface of the conductive base part 110. At this time, a) and b) may be in the reverse order.

c) The supporting bar 208 and a backup plate 204 are set on the base plate 201, and the heater part 105 is mounted on the backup plate 204.

d) The side wall 202 is mounted on the base plate 201.

e) The cover 203 which secures the conductive base part 110 on the side wall 202 is mounted at a position where the adhesion surface of the conductive base part 110 is facing the adhesion surface of the heater part 105.

At this time, the adhesion surface of the conductive base part 110 and the adhesion surface of the heater part 105, by all means, need not be parallel. A plurality of the supporting bars 208 is installed, and as each supporting bar can be activated individually, the adhesion surface can be tightly pressed even in the case where the adhesion surface is not in parallel.

f) A vacuum pump is activated to form vacuum pressure inside the adhesion container.

Vacuum pressure herewith means the pressure less than the atmospheric pressure and the pressure possible for not forming foams to a level not having practical problems.

g) By maintaining under vacuum condition, the supporting bar is raised so that the adhesion surfaces of the conductive base part and the heater part are pressed.

h) While pressing, the inner pressure of the adhesion container is increased, thereby closely attaching the adhesion surfaces. The pressure herein may be the atmospheric pressure.

Processing the adhesion in the above order, having no air gap and good adhesive ability on the adhesion surface can be obtained.

From conducting the adhesion process under vacuum atmosphere, the foams forming can be prevented from penetrating and remaining on the adhesion surfaces, thereby obtaining excellent adhesion. The vacuum pressure herewith means the pressure less than the atmospheric pressure and the pressure possible for not forming foams to a level where the practical problems do not occur. Preferably, the pressure is 3 kPa or less.

Further, at least any two of the supporting part 120 and the heater part 105, and the conductive base part 110 are inserted into the adhesion container. After reducing the pressure therein, the outer circumference of adhesive layer 115 or 116 is firstly contacted no that after forming a closed space which forms the adhesive layer and the surface to be adhered, it is preferred to increase the inner pressure of the adhesion container. By contacting the outer circumference first, a closed space between the adhesive layer and the surface to be adhered is formed. Afterward, by increasing the inner pressure of the adhesion container, the inner pressure of the above-mentioned space is reduced relatively, thereby the space is pressed in which the adhesive layer and the surface to be adhered can be attached easily. Further, by blocking the air from penetration, the foams can be prevented from penetrating into the adhesive surface, thereby obtaining an excellent adhesion surface without having pores thereon.

More particularly, surface of the adhesion surface 114 is formed on the concave portion surface, and the conductive base part 110 and the heater part 105 are attached through the adhesion surfaces using the adhesion container as illustrated in FIG. 10 is preferred. The order of adhesion is the same to that of the present invention as illustrated is FIG. 11. Having the shape of the adhesion surface as the concave portion surface, the adhesion surface contacts the outer circumference while inner circumference forms the closed space under vacuum condition. In such condition, applying pressure can closely attach the adhesion surface without remaining the foams.

In order to first contact the outer circumference to the subject to be adhered, there are methods such as forming the surface of the adhesive into the concave portion form then faced to the subject to be attached or, on the contrary, processing and/or modifying the subject into the concave portion form then first contacted the outer circumference of the adhesive and the like. Either way, by reducing gap between surface of the adhesive and surface of the subject, especially, reducing outer side of the gap than center portion thereof, it can prevent the foams from remaining on the adhesion surface and obtain good adhesion.

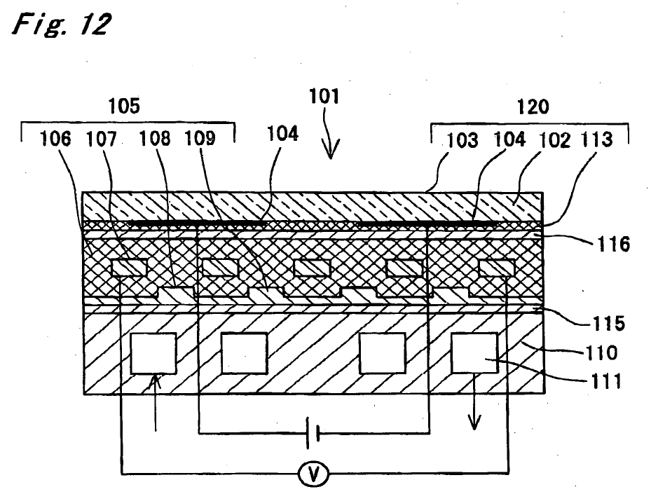

Next, another embodiment of the wafer supporting member 101 of the invention will be described iii detail. As illustrated in FIG. 12, to a main surface other than the mounting surface 103 which mounts wafer of the planar body 102, the film forming means such as an ion-plating method, a PVD method, a CVD method, a sputtering method and a plating method and the like is used to form the adsorption electrodes 104, whereon the adhesive layer 113 is formed to produce a supporting part 120 is possible. The adsorption electrodes 104 can be formed of metals such as Ti, W, Mo and Ni, and carbides thereof and the like.

In addition, the conductive base part 110 and the supporting part 120, and the heater part 105 are all coupled and integrated using the adhesive to produce the wafer supporting member 101. The wafer supporting member 101 has the mounting surface 103 for carrying the wafer W. The mounting surface 103 has the adsorption electrodes 104 applied with a voltage while the wafer W is under electrostatic adsorption. The wafer W can be evenly heated by flowing current to the heater part 105.

In such case, the adhesive layers 110 and 116 used in between of the conductive base part 110, the supporting part 120 and the heater part 105 may preferably be formed using a rubber adhesive such as insulating silicone so that it can relieve thermal stress caused by heating and force generated by difference of thermal expansion, and/or support electrical insulation between respective parts.

Hereinafter, other production methods and structures of the wafer supporting member 101 of the present invention are described.

For the planar body 102, a planar ceramic body is used to improve corrosion-resistance or abrasion-resistance of the mounting surface. Herein, heat-uniformity planar body 112 has the thermal expansion coefficient close to that of the planar ceramic body which composes the planar body 102 so that it leads to reduction of modification of the mounting surface at an elevated temperature. Such heat-uniformity planar body 112 contains, a combined materials consisting of copper or silver, aluminum and the like with high thermal conductivity and high melting metals such as tungsten or molybdenum and the like with low thermal expansion.

The supporting member 120 is produced by printing the adsorption electrodes 104 on a pre-prepared ceramic green sheet when the planar body 112 is formed: laminating the other ceramic green sheet over the printed sheet to produce a formed body embedding the adsorption electrodes 104; and burning the formed body after the degreasing process. Further, the materials for the adsorption electrodes 104 may consist of the GA group elements on the periodic table such as tungsten W, molybdenum Mo, the 4A group high melting-point metal elements such as Ti, or alloys thereof, and the conductive ceramics such as WC, MoC, TiN, etc.

Hereinabove, it was described in the embodiments that the heater part 105 was adhered and secured to the supporting part 120 and the conductive base part 110, but it is of course understood that the invention adapts the wafer supporting member 120n using a metal plate such as aluminum as the supporting part 120; the heater part 105 integrated to the supporting part 120 by means of thermocompression; and the conductive base part 110 fitted to the metal plate.

Furthermore, the invention is not limited to the above described examples and/or embodiments which are presented only for the purpose of illustration, and the variations and/or the modification without departing from the scope of the present invention may be of course apparent to those having ordinary skills in the art.

### EXAMPLE 12

A planar body made of a circular aluminum oxide sintered material and having the outer diameter of 200 mm and the thickness of 1 mm was prepared. The planar body was under grinding then finishing processes for processing one main surface thereof to form amounting surface with the flatness of 10 μm, the surface roughness of 0.5 μm in terms of the arithmetical mean roughness Ra.

The polyimide film having the thickness of 0.41 mm and alternative polyimide film having the thickness of 0.2 mm were inserted in a heater pattern made of a metallic nickel. This prepared heater pattern was pressed out to a conductive base part made of aluminum to form an integrated body. The concave portions generated on the polyimide film surface was filled with the epoxy adhesive then was subjected to the de-foaming process of the adhesive under vacuum condition not more than 2.6 kPa, followed by heat-curing the adhesive.

The epoxy resin surface comprising the above adhesive was ground using A rotary grinder to form a smooth surface having the flatness of 10 μm or less of the adhesive surface. At this time, it should be ground to have the surface roughness in a range of 0.1 μm to 5 μm in terms of the arithmetical mean roughness Ra. Additionally, the polyimide film have the thermal conductivity of 0.34 W/(m·K) while the epoxy resin being adjusted to have the thermal conductivity identical to that of the polyimide film by adding a metallic filler.

After then, silicon adhesive coated the above epoxy resin surface and the above planar body mounted over the coated epoxy resin surface. Under vacuum condition not more than 2.6 kPa, de-foaming treatment was carried out for the adhesive. After applying the adhesive under atmosphere, it was adhered and cured to produce samples Nos. 201 to 205, and 208.

Using the adhesion container as illustrated in FIG. 10, the adhesion between the conductive base part and the heater part of sample No. 206 were conducted according to the procedure illustrated in FIG. 11.

The sample No. 207 has the adhesion surface 114 in the concave portion form, and the adhesion between the conductive base part and the heater part was conducted using the adhesion container illustrated in FIG. 10 according to the procedure illustrated in FIG. 11 as described above for sample No. 206.

Each of the adhesive layers was prepared by the following processes.

The samples Nos. 201 and 202 was produced by forming silicone adhesive with 0.7 mm in thickness using the screen-printing method, followed by adhesion to cure it. The samples Nos. 203 to 207 were obtained by coating the adhesive up to 0.2 mm thickness using the screen-printing method, followed by the repeatedly printing and drying processes to form the desired adhesive layer of 0.7 mm. Lastly, the adhesive layer was adhered and cured after the printing.

In addition, the silicone layers in the samples Nos. 201 to 208 had all a constant thickness of 0.7 mm.

The temperature deviation in the wafer surface was determined by pouring cooled water controlled to 30° C. at a cooling passage of the conductive base part in the wafer supporting member; mounting the wafer W on the mounting surface; applying the voltage to the heater while measuring the temperature of the surface of the water W by means of Thermo-Viewer to control the average temperature of the mounting surface to 60° C.; then determining the temperature deviation in the wafer surface. Such temperature deviation may be represented by the value of highest temperature minus lowest temperature in the wafer surface measured using Thermo-Viewer.

The results are shown in Table 11

TABLE 11

| | | Arithmetic | | | | |
|---|---|---|---|---|---|---|
| | | mean surface | | | | |
| | | roughness | | | | |
| | | Ra of | | | | |
| | Method | resin filled | | | | |
| | for | in concave | | Temperature in wafer W side | | |
| | forming | portion of | | Highest | Lowest | Temperature |
| Sample | adhesive | heater | Adhesion | temperature | temperature | variation |
| No. | layer | part | method | (° C.) | (° C.) | (° C.) |
| 201* | Screen | 0.1 | under | 67.8 | 53.4 | 11.2 |
| | printing: | | atmosphere | | | |
| | once | | | | | |
| 202 | Screen | 1 | under | 64.5 | 56.7 | 7.0 |
| | printing: | | admosphere | | | |
| | once | | | | | |
| 203 | Screen | 1 | under | 62.8 | 57.0 | 5.8 |
| | printing: | | atmosphere | | | |
| | multiple | | | | | |
| | times | | | | | |
| 204 | Screen | 0.2 | under | 63.1 | 57.2 | 5.9 |
| | printing: | | atmosphere | | | |
| | multiple | | | | | |
| | times | | | | | |
| 205 | Screen | 2 | under | 63.2 | 57.3 | 5.9 |
| | printing: | | atmosphere | | | |
| | multiple | | | | | |
| | times | | | | | |
| 206 | Screen | 1 | Adhesion | 62.5 | 58.7 | 3.8 |
| | printing: | | container | | | |
| | multiple | | | | | |
| | times | | | | | |
| 207 | Screen | 1 | Adhesion | 62.1 | 59.2 | 2.9 |
| | printing: | | container | | | |
| | multiple | | | | | |
| | times | | | | | |
| 208 | Screen | 3 | under | — | — | — |
| | printing: | | atmosphere | | | |
| | once | | | | | |

*means beyond the range of the present invention.

It was found that the sample No. 201 having the surface roughness of 0.1 showed the high temperature deviation of about 11.2° C.

In the case of the sample No. 208, Ra was high such as 3. The sample represented by the great current leak out of the heater to the conductive base member. Therefore, it cannot heat the heater.

On the contrary, the samples Nos. 202 to 207 as the wafer supporting member according to the invention showed that Ra for the resin filled in the heater was in a rang of 0.1 μm to 2 μm and the temperature deviation was as low as 7.8° C. Therefore, it was expected the inventive wafer is preferable.

The sample No. 202 showed the temperature deviation of 7.8° C., while the samples Nos. 203 to 207 exhibited relatively low temperature deviation of 5.9° C., thus, were not preferable, which were produced by laminating the adhesive layer between the heater part and the conductive base part with an alternative resin layer thinner than the above adhesive resin several times. It is expected that the reason is because no air gaps are generated on the adhesive layer.

When the adhesive layer is formed, the samples Nos. 206 and 207 which were adhered under vacuum pressure showed relatively lower temperature deviation of 3.8° C., were found preferable. This was a result of not forming pores on the adhesive layer.

Especially, the sample No. 207 which was produced by the adhesion after forming the concave portion of the adhesive layer in the adhesion container, showed low temperature deviation of 2.9° C. of the wafer, exhibited the excellent characteristics.

### EXAMPLE 13

Regarding the wafer supporting member as illustrated in FIG. 8, prepared was the planar body made of a ceramic sintered body in the disc-shaped having the outer diameter of 200 mm and the thickness of 1 mm with a different thermal conductivity (α) pt the planar body as the mounting surface. Grinding one main surface of this planar body, obtained was the mounting surface having Ra of 0.5 μm and the flatness of 10 μm.

Using a plating method, a Ni layer having a thickness of 10 μof a semidisc-shaped was coated to compose a disc-shaped on the other main surface of the planar body to form a pair of adsorption electrodes were produced. The heater part was obtained by changing the thermal conductivity of the resin filled in the concave portion surface part of the insulating resin. The same procedure described in Example 12 for the sample No. 103 was repeated to adhere the supporting part, the heater part and the conductive base part. The insulating resin was polyimide resin having the thermal conductivity (α) of 0.34 W/(m·K). The resin filled in the concave portions oil surface of the insulating resin was epoxy adhesive and its thermal conductivity (α) was adjusted by adding metal filler. The samples were evaluated according to the same procedure in Example 12.

The results are shown in Table 12.

TABLE 12

| | | Thermal | | | |
|---|---|---|---|---|---|
| | Thermal | conductivity | | | |
| | conductivity | of | | | |
| | of | insulating | | | |
| | resin | resin/thermal | | | |
| | filled in | conductivity | | | |
| | concave | of | | | |
| | portion | resin | Temperature in wafer W side | | |
| | of | filled in | Highest | | |
| Sam- | insulating | concave | temper- | Lowest | Temperature |
| ple | resin | portion | ature | temperature | variation |
| No. | (W/(m · k)) | (%) | (° C.) | (° C.) | (° C.) |
| 221 | 0.255 | −25 | 64.4 | 59.3 | 5.1 |
| 222 | 0.289 | −15 | 63.1 | 58.7 | 4.4 |
| 223 | 0.306 | −10 | 62.1 | 58.3 | 3.8 |
| 224 | 0.340 | 0 | 61.9 | 58.3 | 3.6 |
| 225 | 0.374 | 10 | 61.8 | 58.0 | 3.8 |
| 226 | 0.391 | 15 | 62.1 | 57.7 | 4.4 |
| 227 | 0.425 | 25 | 62.1 | 57.1 | 5.0 |

From the result, it was found that the temperature deviation at 60° C. was as low as 5.1° C. for all samples. However, for the samples Nos. 222 to 226 having the same thermal conductivity for the insulating resin 106 and the resin filled in the concave portion of the heater part, the temperature deviation at 60° C. was lowered to 4.4° C. Therefore, it was understood that this can reduce the temperature deviation in the wafer W surface and improve heat-uniformity.

For the samples Nos. 223 to 225 having the ratio of the thermal conductivity of the resin 109 to that of the insulating resin 106 in a range of −10 to +10% showed the temperature deviation the lowest such as 3.8° C. and determined preferable.

This result is of course the same for the adhesive as the resin 109 made of a silicone resin.

### EXAMPLE 14

Regarding the wafer supporting member of the invention as illustrated in FIG. 8, the same procedure as described in Example 12 was repeatedly evaluated, except that the heater part has the average thickness in a range of 0.005 mm to 1.5 mm. Alternatively, it was determined the time taken from application of the voltage to the heater until the average temperature of the mounting surface reached 60° C.

The resin filled in the concave portion of the heater part is an epoxy resin and the average thickness of the heater part resin is defined from the upper surface of the heater to the surface of the heater part which includes thickness of the insulating resin and the thickness of the resin 109, after measuring 5 points from the thickness then taking average of them as the average thickness.

The results are shown in Table 13.

TABLE 13

| | Average | | | | |
|---|---|---|---|---|---|
| | thickness | Temperature | | | Until the |
| | of | in wafer W side | | | temperature |
| | resin of | Highest | | | of the |
| Sam- | heater | temper- | Lowest | Temperature | loading side |
| ple | part | ature | temperature | variation | reaches 60° C. |
| No. | (mm) | (° C.) | (° C.) | (° C.) | (sec) |
| 231 | 0.01 | 60.3 | 58.2 | 2.1 | 7.4 |
| 232 | 0.10 | 60.3 | 57.5 | 2.8 | 8.0 |
| 233 | 0.50 | 60.5 | 57.2 | 3.3 | 9.3 |
| 234 | 0.70 | 60.5 | 56.2 | 4.3 | 12.0 |
| 235 | 1.00 | 60.2 | 55.8 | 4.4 | 14.3 |
| 236 | 1.50 | 60.7 | 55.4 | 5.3 | 17.4 |

From the result, it was found that the temperature deviation at 60° C. was as low as 5.3° C. for all samples. However, samples No. 231 to 235 had average thickness in a range of 0.01 mm to 1 mm and the lower temperature deviation such as 4.4° C. In addition, it was found that the time taken until the average temperature reached 60° C. was as short as 14.3 seconds, therefore; was determined preferable.

On the contrary, the sample No. 236 having large thickness of 1.5 mm showed the larger temperature deviation such as 5.5° C. and time taken until the average temperature reached 60° C. was as long as 17.4 seconds.

Further, for samples having average thickness of the resin of 0.005 mm, it was found that the insulating resin consisting of polyimide resin in the heater part cannot be under flat-processing or grinding at thickness processing because of its damage, nor under evaluation.

### EXAMPLE 15

Next, regarding the wafer supporting member as illustrated in FIG. 8 or 9, it was produced by changing thermal conductivity (α) of the planar body which forms the supporting part A planar body made of a ceramic sintered body in the disc-shaped having an outer diameter of 200 mm and a thickness of 1 mm was prepared, and one main surface of the planar body was ground for obtaining the mounting surface having a flatness of 10 μm and an arithmetic mean roughness (Ra) as a surface roughness of 0.5 μm.

Next, using a plating method, a Ni layer having a thickness of 10 μm of a semidisc-shaped was coated to compose a disc-shaped on the other main surface of the planar body to form a pair of absorption electrodes were produced. Further, accordingly with Example 12 of the sample No. 203 wafer supporting member of the invention, the heater part and the conductive base part was adhered to obtain the samples Nos. 241 and 242 wafer supporting member.

In addition, to a lower surface of the planar body, the heat-uniformity planar body 112 was again installed, and by adhering the heater part and the conductive base part, the samples Nos. 243 and 244 wafer supporting member was obtained.

Further, the temperature deviation was calculated by injecting cooled water controlled to a temperature of 30° C. at a cooling passage of the conductive base part comprised in each wafer supporting member, and controlling the mounting surface to a temperature of 60° C. by applying voltage to the heater pattern, followed by measuring temperature using Thermo-Viewer. Herein, the materials for forming supporting part such as an alumina sintered material having thermal conductivity (α) of 25 W/(m·K), an aluminum nitride sintered material having thermal conductivity (α) of 150 W/(m·K), a copper and tungsten combined material having thermal conductivity (a) of 180 W/(m·K) and a silver plate having thermal conductivity (α) of 419 W/(m·K) were used. The results are shown in Table 14.

TABLE 14

| | | | Heat-uniformity | | | | |
|---|---|---|---|---|---|---|---|
| | Material | | planar body 112 | | | | |
| | of planar | Thermal | provided on | Thermal | Temperature in wafer | | |
| | body 102 | conductivity | lower surface | conductivity of | W side | | |
| | to form | of planar | of planar body | heat-uniformity | Highest | Lowest | Temperature |
| Sample | loading | body 102 | 102 to form | planar body 112 | temperature | temperature | variation |
| No. | side | (W/m · K) | mounting surface | (W/m · K) | (° C.) | (° C.) | (° C.) |
| 241 | Alumina | 25 | No | — | 61.9 | 56.4 | 5.5 |
| | sintered | | | | | | |
| | material | | | | | | |
| 242 | Aluminum | 50 | No | — | 62.1 | 58.4 | 3.7 |
| | nitride | | | | | | |
| | sintered | | | | | | |
| | material | | | | | | |
| 243 | Aluminum | 150 | Cu—W | 150 | 61.1 | 59.4 | 1.7 |
| | nitride | | | | | | |
| | sintered | | | | | | |
| | material | | | | | | |
| 244 | Aluminum | 150 | Ag | 419 | 60.8 | 60.0 | 0.8 |
| | nitride | | | | | | |
| | sintered | | | | | | |
| | material | | | | | | |

As a result, the temperature deviation at 60° C. was lowered by 5.5° C. or less when the thermal conductivity (a) was 50 to 419 W/(m·K).

Further, it was found that the temperature deviation was lowered by 3.7° C. or less when the thermal conductivity in the direct parallel to the mounting surface of the supporting part was 50 W/(m·K) or more, thereby resulting in improvement of heat-uniformity of the mounting surface.

### EXAMPLE 16

Next, regarding the wafer supporting member as illustrated in FIG. 8, the evaluation was conducted accordingly with the sample No. 203 of Example 12, except that the heater part and the conductive base part has the adhesive layer having a thickness in a range of 0.005 mm to 1.5 mm. Further, the time taken from lowering the heated temperature of 60° C. to the cooled temperature of 30° C. as the cooling water was measured.

The results are shown in Table 15.

TABLE 15

| | Average | | | | |
|---|---|---|---|---|---|
| | thickness | | | | Until the |
| | of heater | Temperature in wafer W side | | | temperature |
| | part and | | | Tem- | of |
| Sam- | conductive | Highest | Lowest | perature | the loading |
| ple | base part | temperature | temperature | variation | side reaches |
| No. | (mm) | (° C.) | (° C.) | (° C.) | 30° C. (sec) |
| 250 | 0.005 | — | — | — | — |
| 251 | 0.01 | 60.1 | 55.7 | 4.4 | 6.3 |
| 252 | 0.10 | 60.4 | 56.2 | 4.2 | 6.9 |
| 253 | 0.50 | 60.3 | 57.6 | 2.7 | 9.3 |
| 254 | 0.70 | 60.4 | 58.0 | 2.4 | 10.4 |
| 255 | 1.00 | 60.2 | 57.7 | 2.5 | 13.4 |
| 256 | 1.50 | 60.5 | 58.0 | 2.5 | 22.8 |

The evaluation of the sample No. 250 having the adhesive layer thickness of 0.005 mm was stopped, because even at the maximum voltage 200 V, the sample was not heated up to 60° C.

Further, in the case of having a greater thickness of 1.5 mm of the adhesive layer, such sample No. 256 exhibited low temperature deviation of 2.5° C. However, 22.8 seconds of long cooling time was required and the thermal response was poor.

On the other hand, the samples Nos. 251 to 255 showed the adhesive layer thickness in a range of 0.01 mm to 1 mm, the temperature deviation was 4.4° C. or less, and the time taken from lowering to the cooled temperature of 30° C. was 13.4 seconds or less, therefore preferred.

### Third Embodiment

Hereinafter, a third embodiment of the invention will be described in detail.

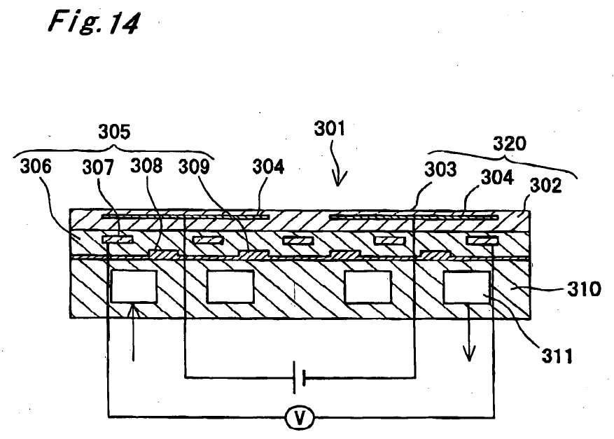

FIG. 14 illustrates one example of the wafer supporting member 1 according to the invention.

The wafer supporting member 301 has the structure having one main surface of the supporting part 320 in a disc-shaped as the mounting surface 303 for mounting the wafer W; having the supporting part 320, which embeds a pair of an electrostatic adsorption electrodes 304 on the mounting surface 303, and the heater 307 embedded in the insulating resin 306; and a heater part 305 having the concave portion in the insulating resin 306 to be filled with the other resin 309 having a composition different from the resin 306, wherein the heater part 305 is interposed between the supporting part 320 and a conductive base part 310.

The conductive base part 310 consists of the conductive materials including, for example, the metal materials such as aluminum and cemented carbide, or composite materials such as said metal materials and the ceramic materials, and may function as an electrode for generating plasma. The conductive base part 310 has a passage 311 inside, through which a cooling medium such as a cooling gas or cooling water flows in order to adjust the temperature of the wafer W placed on the supporting part 320 to a predetermined temperature.

For the planar body 302 constructing the supporting part, a sintered body such as an alumina-based sintered body, a silicon nitride-based sintered body, an aluminum nitride based sintered body, a yttrium-aluminum-garnet-based sintered body (hereinafter refer to as ‘YAG’) and a single-crystalline alumina (sappier) can be used. Among them, the aluminum nitride-based sintered body has at least 50 W/(m·K), or even at least 100 W/(m·K) of the thermal conductivity, and thus is more preferable to reduce the temperature difference of the inside of the wafer W.

The wafer supporting member 301 can be vacuum sealed by forming the heater 307 using a metal foil or a metal wire and inserting the insulating resin 306 in the form of the sheet film having a constant thickness into the upper and lower surfaces thereof where thermocompression and the like is applied. The top and bottom of the insulating resin 306 of the heater part 305 forms an unevenness depending on the thickness of the heater 307 according to the shape thereof. Therefore, in order to fill the concave portion of the unevenness the alternative resin 309 having different composition from that of the insulating resin 306 can be filled in the concave portion 308 and form the heater part 305.

More particularly, the resin 309 comprises preferably a thermo-curing resin such as an adhesive. After pouring the resin 309 to fill the concave portions 308, sufficiently de-foaming the resin to remove foams and heating and curing the resin, the surface of the treated resin is ground using a rotary grinder, a surface grinder or the like to obtain the heater part 305 having a flat and smooth surface of the resin 309.

The upper surface of the heater part 305 and the lower surface of the supporting part 320, and the lower surface of the heater part 305 and the upper surface of the conductive base part 310 can be uniformly in contact, so that the heater 307 made of a metal foil generates heat by flowing electric current into the heater 307 and evenly transfers the generated heat over the entire surface of the supporting part 320.

Hereinabove, the concave portions 308 was described for the case wherein it is located on the side of the conductive base part 310. However, it is a matter of course that the same effect can hp accomplished by filling the resin 309 having composition different from that of the insulating resin 306 into the concave portions 108 when the concave portions 308 are located on the side of the supporting part 120.

By flowing the electric current to the electrostatic adsorption electrodes 304 equipped in the planar body 302 to construct the supporting part 320 and expressing the electrostatic adsorption force, it can adsorption-secure the wafer W to the mounting surface 303 and enhance thermal conductivity between the mounting surface 303 and the wafer W and, as a result, efficiently heat the wafer W.

Regarding the heater part 305 having the heater 307 embedded in the insulating resin 306, it is preferable to have a polyimide resin as the insulating resin 306. The polyimide resin has an excellent heat-resistance and a favorable electric-insulation so that a thickness of the resin may be preferably reduced. Further, it is much preferable that the heater 307 can be easily embedded into the insulating resin 306 by the thermocompression. Even though the polyimide resin was used to embed the heater 307, its thickness is only in a range of 0.05 mm to 0.5 mm. Therefore, because the thickness can be reduced, it was possible to increase uniformity of the wafer W even if the polyimide resin has relatively low thermal conductivity.

Further, in order to evenly transfer the heat generated from the heater 307 to the wafer W, it is preferable to have the identical thermal conductivity of the insulating resin 306 to the other resin 309 but having different composition from that of the resin 306, which filled the concave portions on the surface of the resin 306. In addition, the term ‘identical to’ in the invention is defined as to having the thermal conductivity of the resin 306 in a range of 0.8 to 1.2 times the thermal conductivity of the resin 309.

When the thermal conductivity of the resin 309 exceeds 1.2 times the thermal conductivity of the resin 306, it is not preferable because the heat generated from the heater 307 is promptly transferred, and the temperature on the thick portion of the resin 309 is increased. On the other hand, when the thermal conductivity of the resin 309 filling the concave portion 308 on the heater surface is less than 0.8 times the thermal conductivity of the resin 306, the heat transfer between the heaters 307 is delayed which result in increase in the temperature deviation at the mounting surface 303 of the supporting part 320. The thermal conductivity of the resin 309 is at a preferable range of 0.9 to 1.1 times the thermal conductivity of the resin 306.

A method for controlling the thermal conductivity of the resin 309 that includes adding a metal powder or a ceramic powder in a range of 0.1 to 10% by mass to the resin 309 to control the thermal conductivity so that the thermal conductivity is substantially the same to the thermal conductivity of the resin 306.

At this time, the resin 309 filled in the concave portions 308 include preferably, an epoxy resin or a silicone resin. The adhesive compose of such resin has less viscosity, and can be tightly filled into the concave portions 308 without penetration of air by applying it on the concave portions 308 of the heater surface for de-foaming.

Especially, the epoxy resin having a sufficient hardness can be obtained when heat-cured, therefore the surface of the resin 309 is ground using the rotary type or multi-functional grinders, thereby adjusting the thickness of the heater part 305 easily and conducting the finishing process on a smooth face is possible simultaneously. Therefore, when the supporting part 320 or the conductive base part 310 is attached thereto, it is occurred in the front portion of each member with excellent precision.

Further, the resin of the heater part 305 has the preferable average thickness in a range of 0.01 to 1 mm. When the average thickness is less than 0.01 nun, the electrical short-circuit is occurred between the heater 307 and the conductive base part which may lead to dielectric breakdown. when the average thickness exceeds 1 mm, heat generated from the heater 307 cannot be transferred rapidly to the supporting part 320 or the conductive base part 310, thereby it is not preferable due to having difficulties in the prompt cooling or the uniformly heating the wafer W. More preferable thickness is in a range of 0.1 mm to 0.5 mm.

Such average thickness are calculated by measuring values at 5 points in a distance from upper surface of the heater 307 in the heater part 305 up to outer side of the heater part then estimating average from the five values.

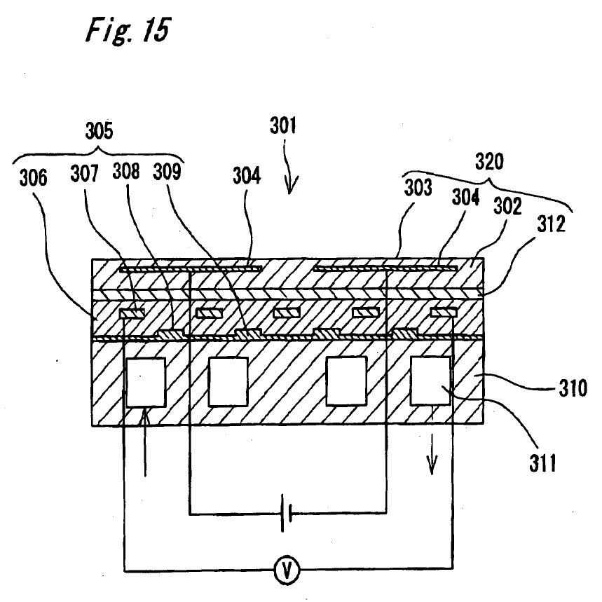

As illustrated in FIG. 15, the supporting part 320 is formed by inserting a planar body 312 made of ceramics having thermal conductivity higher than that of the planar body 302 into lower surface of the planar body 302 and integrating them. Such construction allows the planar body 302 or the mounting surface 303 of the planer body 312 to have, but partially, the thermal conductivity of 50 to 419 W/(m·K) in a parallel direction. As a result, the temperature variation may be lowered and the heat-uniformity may be increased inside the wafer W surface.

Accordingly, the thermal conductivity in the parallel direction to the mounting surface 303 of the planar body 302 or the planar body 312 is preferably in a range of 50 to 419 W/(m·K) This is because when the thermal conductivity in the parallel direction to the mounting surface 303 of the planar body 302 or the planar body 312 is less than 50 W/(m·K), the time is needed until the temperature becomes constantly maintained in the direction parallel to the mounting surface 303 during that the heat generated from the heater 307 is transferred to the mounting surface 303, which result in increase in the temperature deviation as well as the time delay from altering the temperature of the wafer W.

On the contrary, when the thermal conductivity in the direction parallel to the mounting surface 303 of the planar body 302 or 312 exceeds 419 W/(m·K), it is difficult to provide industrially available materials at a low cost since the high frequency materials such as silver cannot be used.

To the planar body 302, a planar ceramic body is used to improve corrosion-resistance or abrasion-resistance of the mounting surface. Herein, the planar body 312 has the thermal expansion coefficient close to that of the planar ceramic body consisting of the planar body 302 so that it leads to reduction of modification of the mounting surface at elevated temperatures. Such planar body contains, a combined materials consisting of copper or silver, aluminum and the like with high thermal conductivity and high melting metals such as tungsten or molybdenum and the like with low thermal expansion.

Next, the production methods of the wafer supporting member 301 and other constructions will be described in detail.

The supporting member 320 is produced by printing the adsorption electrodes 304 on a pre-prepared ceramic green sheet when the planar body 302 was formed; laminating the other ceramic green sheet over the printed sheet to produce a formed body embedding the adsorption electrodes 304; and burning the formed body after the degreasing process. Further, materials for the adsorption electrodes 304 may consist of the 6A group elements on the periodic table such as tungsten W, or molybdenum Mo, the 4A group high melting-point metal elements such as Ti, or alloys thereof, and the conductive ceramics such as WC, MoC, TiN, etc.

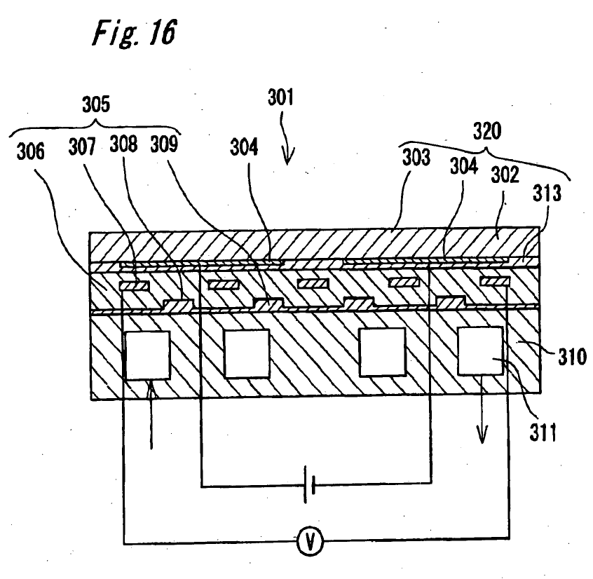

Next, as illustrated in FIG. 16, to a main surface other than the mounting surface 303 which mounts wafer of the planar body 302, the film forming means such as an ion-plating method, a PVD method, a CVD method, a sputtering method and a plating method and the like is used to form the electrostatic adsorption electrodes 304, whereon the adhesive layer 313 is formed to produce a supporting part 320 is possible. The adsorption electrodes 304 can be made of metal such as Ti, W, Mo and Ni, and carbides thereof and the like.

In addition, the conductive base part 310 and the supporting part 320, and the heater part 305 are all coupled and integrated using the adhesive and the like. The mounting surface 303 on the supporting part 320 receives the wafer W and has electrostatic function. The wafer W can be evenly heated by flowing current to the heater part 305.

In this regards, adhesion surfaces of all of the conductive base part 310, the supporting part 320, and the heater part 305 preferably consist of rubber status adhesives such as insulating silicone so that it can relieve thermal stress caused by heat, force caused by difference of the thermal expansion, and the support electric-insulation characteristics between respective parts. Alternatively, in order to efficiently and evenly distribute every portion the heat from the heater part 305, the adhesive layer is preferably controlled for thickness deviation of the adhesive layer in a range of 5 μm to 50 μm. More particularly, the adhesive is applied by means of screen-printing then adhered loading weight evenly to reduce the thickness deviation of the adhesive layer and uniformly distribute the mount.

Hereinabove, it was described about the embodiments that the heater part 305 is adhered and secured to the supporting part 320 and the conductive base part 310, however, it is of course understood that the invention adapts the supporting member 301 using a metal plate such as aluminum or the like as the supporting part 32U; the heater part 305 integrated to the supporting part 320 by means of the thermocompression; and the conductive base part 310 is fitted to the metal plate such as aluminum or the like.

Furthermore, the invention is not limited to the above described examples and/or embodiments which are presented only for the purpose of illustration, and the variations and/or modification without departing from the scope of the invention may be of course apparent to those having ordinary skills in the art.

### EXAMPLE 17

This example is for evaluating temperature deviation of the wafer y on the mounting surface when each of the heaters generates heat, by preparing the wafer supporting member comprising an epoxy resin filled in the concave portion on the surface of the insulating resin (sample No. 301) and the wafer supporting member of the invention, and another wafer supporting member (sample No. 302) without filling the resin in the concave portions.

Regarding the wafer supporting member according to the invention, prepared was the planar body made of a ceramic sintered body in the disc-shaped having the outer diameter of 200 mm and the thickness of 1 mm. The one main surface of this planar body was ground for obtaining the mounting surface having an arithmetical mean roughness Ra of 0.5 μm and a flatness of 10 μm. A polyimide film having the thickness of 0.41 mm and the other polyimide film having the thickness of 0.2 mm were inserted in a heater pattern made of a metallic nickel. This prepared heater pattern was pressed out to a conductive base part made of aluminum to form an integrated body. The concave portions generated on the polyimide film surface was filled with an epoxy adhesive then was subjected to de-foaming process of the adhesive at the vacuum condition not more than 2.6 kPa, following by heat-curing the adhesive.

The epoxy resin surface comprising the above adhesive was ground using a rotary grinder to form a smooth surface having the flatness of 10 μm or less.

At this time, the polyimide film have the thermal conductivity of 0.34 W/(m·K) while the epoxy resin being adjusted to have the thermal conductivity identical to that of the polyimide film by adding metallic filler.

After, the silicon adhesive coated the above epoxy resin surface and the above planar body mounted over the coated epoxy resin surface. Under vacuum condition not more than 2.6 kPa, the de-foaming was carried out for the adhesive.

Meanwhile, regarding the other wafer supporting member, it was produced by coating silicone adhesive without filling epoxy adhesive into the concave portions on the polyimide film surface facing the conductive base part; and loading the planar body over the base part and curing the adhesive after de-foaming of the adhesive under vacuum condition not more than 2.6 kPa.

And, the temperature deviation in the wafer surface was determined by pouring cooling water controlled to 30° C. at a cooling passage of the conductive base part in the wafer supporting member; loading the wafer W on the mounting surface; applying voltage to the heater while measuring temperature of surface of the wafer W by means of Thermo-Viewer to control average temperature of the mounting surface to 60° C.; then determining the temperature deviation in the wafer surface. Such temperature deviation may be calculated by the value of the highest temperature minus the lowest temperature in the wafer surface using Thermo-Viewer.

The results are shown in Table 16

TABLE 16

| | Existence of | | | |
|---|---|---|---|---|
| | resin filled in | | | |
| | concave portion | Temperature in wafer W side | | |
| | on surface of | Highest | Lowest | Temperature |
| Sample | insulating | temperature | temperature | variation |
| No. | resin | (° C.) | (° C.) | (° C.) |
| 301 | Yes | 62.9 | 57.1 | 5.8 |
| 302* | No | 67.1 | 52.8 | 14.3 |

*represents other than the present invention

From the results, the sample No. 302 as a conventional wafer supporting member showed increased temperature deviation at 60° C. of 140.3° C. However, the present wafer supporting member, sample No. 301 exhibited relatively smaller temperature deviation at 60° C. of 5.8° C., thus, it was found that the temperature variation in the wafer W surface can be reduced.

1. A supporting member for wafer comprising:
an adsorption part of an insulating sheet having a pair of main surfaces, one of which serves as a mounting surface for mounting a wafer and so on and the other of which has an adsorption electrode covered by an insulating layer;
a resin layer part provided below the adsorption part; and
a conductive base part provided below the resin layer part and having a passage for allowing a cooling medium to flow,
wherein the adsorption part has a thickness in a range of 0.02 to 10.5 mm.

2. The wafer supporting member according to claim 1, wherein the adsorption part has a thickness in a range of 0.02 to 2.0 mm.

3. The wafer supporting member according to claim 1, wherein the resin layer part has a volume resistivity in a range of 10⁸ to 10¹⁴ Ω·cm.

4. The wafer supporting member according to claim 1, wherein the resistance value between the mounting surface of the adsorption part and the conductive base part is in a range of 10⁷ to 10¹³ Ω.

5. The wafer supporting member according to claim 1, wherein the resin layer part is mainly composed of at least one of a silicone-based resin, a polyimide-based resin, a polyamide-based and an epoxy-based resin.

6. The wafer supporting member according to claim 1, wherein the resin layer part contains conductive particles in a range of 0.01 to 30% by volume.

7. The wafer supporting member according to claim 1, wherein the insulating sheet is composed of ceramics.

8. The wafer supporting member according to claim 7, wherein the insulating sheet and the insulating layer are composed of the same ceramics.

9. The wafer supporting member according to claim 7, wherein the insulating sheet is mainly composed of any one of aluminum oxide, a rare-earth oxide and a nitride.

10. The wafer supporting member according to claim 1, wherein the insulating sheet is composed of amorphous ceramic and the thickness between the mounting surface and the adsorption electrode in the insulating sheet is in a range of 10 to 200 μm.

11. The wafer supporting member according to claim 10, wherein the insulating sheet contains a rare gas element in a range of 1 to 10% by atom and has a Vickers hardiness in a range of 500 to 1000 HV0.1.

12. The wafer supporting member according to claim 1, wherein the conductive base part is composed of A) a metal component selected from the group of aluminum and an aluminum alloy and B) a ceramic component selected from the group of silicon carbide and aluminum nitride, the content of the ceramic component being ranged from 50 to 90% by mass.

13. The wafer supporting member according to claim 1, further comprising a heater part provided with an insulating resin layer having heaters embedded therein, between the resin layer part and the conductive base part,
wherein concave portions are formed on a surface of the insulating resin layer opposite to the conductive base part and filled with a resin having a composition different from that of the insulating resin layer, and
the heater part and the conductive base part are bonded to each other with an adhesive layer interposed therebetween.

14. The water supporting member according to claim 13, wherein the insulating resin layer filled in the concave portions is composed of an epoxy or a silicone resin.

15. The wafer supporting member according to claim 13, wherein the insulating resin layer of the heater part has an average thickness in a range of 0.01 to 1 mm.

16. The wafer supporting member according to claim 13, wherein the adhesive layer between the heater part and the conductive base part has a thickness in a range of 0.01 to 1 mm.

17. The wafer supporting member according to claim 13, wherein the adhesive layer is formed by laminating a plurality of resin layers each having a thickness smaller than that of the adhesive layer between the heater part and the conductive base part.

18. The wafer supporting member according to claim 17, wherein the adhesive layer is formed by laminating a plurality of resin layers between the heater part and the conductive base part by means of a screen printing.
